(19) United States
(12) Patent Application Publication
(10) Pub. No.: US 2009/0323750 A1
(43) Pub. Date: Dec. 31, 2009

(54) SEMICONDUCTOR LASER DEVICE AND METHOD OF MANUFACTURING THE SAME AS WELL AS OPTICAL PICKUP

(75) Inventors: Daijiro Inoue, Kyoto-shi (JP); Kiyoshi Oota, Neyagawa-shi (JP); Yoshiki Murayama, Hirakata-shi (JP); Ryoji Hiroyama, Kyo-tanabe-shi (JP); Hiroki Ohbo, Hirakata-shi (JP); Seiichi Tokunaga, Toyonaka-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/492,808

(22) Filed: Jun. 26, 2009

(30) Foreign Application Priority Data
Jun. 27, 2008 (JP) 2008-168420
Jul. 7, 2008 (JP) 2008-176731
Jun. 18, 2009 (JP) 2009-145255

(51) Int. Cl. H01S 5/00; H01L 21/00; H01S 5/028

(52) U.S. Cl. 372/46.01; 438/22; 372/49.01; 257/E21.002; 372/50.21

(57) ABSTRACT

A semiconductor laser device includes a semiconductor device layer having an emission layer and formed with a current path on a semiconductor layer in the vicinity of the emission layer, a current blocking layer formed in the vicinity of the current path, and a heat-radiation layer formed to be provided at least in the vicinity of a region formed with a cavity facet of the semiconductor device layer and be located above the current path, and having thermal conductivity larger than that of the current blocking layer.

### CROSS-REFERENCE TO RELATED APPLICATIONS

The priority application numbers JP2008-168420, Semiconductor Laser Device, Jun. 27, 2008, Kiyoshi Oota et al, JP2008-176731, Semiconductor Laser Device and Method of Manufacturing the Same, Jul. 7, 2008, Daijiro Inoue et al, JP2009-145255, Semiconductor Laser Device and Method of Manufacturing the Same as well as Optical Pickup, Jun. 18, 2009, Daijiro Inoue et al, upon which this patent application is based are hereby incorporated by reference.

### BACKGROUND OF THE INVENTION

1. Field of the Invention

The present invention relates to a semiconductor laser device and a method of manufacturing the same as well as an optical pickup, and more particularly, it relates to a semiconductor laser device comprising a semiconductor device layer formed with a current path on a semiconductor layer around an emission layer and a method of manufacturing the same as well as an optical pickup.

2. Description of the Background Art

A semiconductor laser device comprising a semiconductor device layer formed with a current path on a semiconductor layer around an emission layer is known in general, as disclosed in Japanese Patent Laying-Open No. 11-186646, for example.

The aforementioned Japanese Patent Laying-Open No. 11-186646 discloses a ZnSe-based semiconductor laser having a ridge stripe structure in which a lower cladding layer, an active layer, an upper cladding layer and the like are successively formed on a substrate and the current path formed on the upper cladding layer is narrowly restricted by an insulating layer (current blocking layer). In this semiconductor laser, the insulating layer (current blocking layer) containing polycrystalline Si is formed through the semiconductor layer (bonding layer) made of polycrystalline ZnS to be in contact with side wall portions of the current path (ridge) formed on the upper cladding layer and the planar portion other than the current path. Thus, heat generated in the semiconductor laser is radiated outward through the insulating layer containing polycrystalline Si. In the semiconductor laser described in the aforementioned Japanese Patent Laying-Open No. 11-186646, a pad electrode made of Au is so formed as to cover an electrode layer (ohmic layer) formed on a surface of the current path (ridge) and the insulating layer (current blocking layer) formed on the side wall portions of the current path. This pad electrode is generally previously formed at a position set inside the device from a cavity facet by a prescribed distance in order to prevent the pad electrode around a cleavage position from hanging by plastic deformation of metal following cleavage of the device and adhering to the cavity facet when the cavity facet of the semiconductor laser is formed. The heat generated in the semiconductor laser is transmitted to the pad electrode through the electrode layer (ohmic layer) or the insulating layer and radiated outward (Au wire bonded to the pad electrode, for example). The heat generated in the semiconductor laser is mainly generated in the emission layer and the current path formed on the semiconductor layer of an upper portion of the emission layer.

In the semiconductor laser device disclosed in the aforementioned Japanese Patent Laying-Open No. 11-186646, however, heat generated from the current path is effectively radiated to some extent on a region formed with the pad electrode through the pad electrode while transmitting from the side walls of the current path to the insulating layer. On a region formed with no pad electrode around the cavity facet, on the other hand, heat is hardly radiated from the insulating layer. In other words, increase of lattice vibration following temperature increase of the cavity facet easily enables a current to flow in defects caused on the cavity facet, and hence a leak current on the cavity facet may be increased. The catastrophic optical damage (COD) may be caused by heat generated in the cavity facet. Thus, it is disadvantageously difficult to suppress thermal degradation on the semiconductor laser device caused by the heat generated in the cavity facet.

### SUMMARY OF THE INVENTION

A semiconductor laser device according to a first aspect of the present invention comprises a semiconductor device layer having an emission layer and formed with a current path on a semiconductor layer in the vicinity of the emission layer, a current blocking layer formed in the vicinity of the current path, and a heat-radiation layer formed to be provided at least in the vicinity of a region formed with a cavity facet of the semiconductor device layer and be located above the current path and having thermal conductivity larger than that of the current blocking layer.

As hereinabove described, the semiconductor laser device according to the first aspect of the present invention comprises the heat-radiation layer formed to be provided at least in the vicinity of the region formed with the cavity facet of the semiconductor device layer and be located above the current path, whereby heat generated on the regions in the vicinity of the cavity facet in heat generated from the current path extending in a cavity direction can be effectively radiated outside through the heat-radiation layer formed above the current path when operating the semiconductor laser device. In other words, even when no pad electrode made of metal provided on the semiconductor laser device is formed on the region in the vicinity of the cavity facet, the aforementioned heat-radiation layer serves the function of facilitating heat radiation from the region in the vicinity of the cavity facet. Thus, thermal degradation on the semiconductor laser device due to heat generated in the cavity facet can be suppressed. Further, the semiconductor laser device comprises the heat-radiation layer having the thermal conductivity larger than the thermal conductivity of the current blocking layer, whereby heat generated in the current path on the region in the vicinity of the cavity facet can be radiated by preferentially conducting the heat to the heat-radiation layer having the thermal conductivity larger than that of the current blocking layer. The heat generated in the current path is effectively radiated from the heat-radiation layer, and hence the temperature increase of the current blocking layer is suppressed. Thus, thermal degradation to the current blocking layer can be reduced.

The aforementioned semiconductor laser device according to the first aspect preferably further comprises a pad electrode formed on a region other than the vicinity of the region formed with the cavity facet of the semiconductor device layer, wherein the heat-radiation layer is formed to be located above the current path of at least a region not formed with the pad electrode. According to this structure, the heat-radiation layer can reliably absorb heat generated from the current path on the region in the vicinity of the cavity facet, even when the electrode made of metal such as Au is not formed on the region in the vicinity of the cavity facet.

In the aforementioned structure comprising the pad electrode, the heat-radiation layer is preferably stacked on a surface of the current blocking layer, and the pad electrode is preferably formed on a region stacked with at least one of the current blocking layer and the heat-radiation layer. According to this structure, the pad electrode is away from the surface of the semiconductor device layer by the thickness of the current blocking layer or the heat-radiation layer and hence a parasitic capacitance (electrostatic capacitance) between the pad electrode and the semiconductor device layer can be reduced. Consequently, high frequency operating characteristics of the semiconductor laser device can be improved.

In the aforementioned structure comprising the pad electrode, the pad electrode is preferably in contact with the heat-radiation layer on the region other than the vicinity of the region formed with the cavity facet. According to this structure, heat generated on the region in the vicinity of the cavity facet can be effectively radiated outside not only through the heat-radiation layer but also through the pad electrode in contact with the heat-radiation layer.

In the aforementioned semiconductor laser device according to the first aspect, a thickness of the heat-radiation layer is preferably larger than a thickness of the current blocking layer. According to this structure, heat generated in the vicinity of the current path is propagated not only in a thickness direction of the excellent heat conductive heat-radiation layer but also in a plane direction of the heat-radiation layer perpendicular to this direction, and hence heat radiation capacity of the laser device can be further improved. Further, parasitic capacitance (electrostatic capacitance) can be further reduced by the increased thickness of the heat-radiation layer.

In the aforementioned semiconductor laser device according to the first aspect, a region other than the vicinity of the current path of the semiconductor device layer is preferably exposed from the current blocking layer, and the heat-radiation layer is preferably formed on an upper surface of the semiconductor device layer exposed from the current blocking layer. According to this structure, heat generated from the current path is radiated on the portion of the heat-radiation layer formed in direct contact with the upper surface of the semiconductor device layer, and hence increase in a temperature of the overall semiconductor laser device can be suppressed. Consequently, reliability of the semiconductor laser device can be improved.

In the aforementioned semiconductor laser device according to the first aspect, the semiconductor device layer is preferably formed with a planar portion and a striped projecting portion protruding upward from the planar portion and extending along a cavity direction on an upper surface, and the current blocking layer preferably covers side surfaces of the projecting portion, so that the current path is formed on the semiconductor layer in the vicinity of the emission layer. According to this structure, thermal degradation due to heat generated in the cavity facet can be easily suppressed also generally in the semiconductor laser device having a ridge structure employing the current blocking layer made of dielectric having small thermal conductivity.

The aforementioned semiconductor laser device according to the first aspect preferably further comprises a metal electrode layer formed on a surface of the current path, wherein the heat-radiation layer is preferably in contact with the metal electrode layer. According to this structure, heat generated from the current path can be effectively conducted to the heat-radiation layer through the metal electrode layer formed on the surface of the current path.

In the aforementioned structure comprising the metal electrode layer, the heat-radiation layer is preferably formed on at least a surface of the metal electrode layer of an upper portion of a region formed with the current path in the vicinity of the cavity facet. According to this structure, heat generated from the current path in the vicinity of the cavity facet can be effectively conducted to the heat-radiation layer through the metal electrode layer formed on at least the surface of the current path.

In the aforementioned structure comprising the metal electrode layer, the semiconductor device layer preferably has a region not formed with the metal electrode layer in the vicinity of the region formed with the cavity facet, and the heat-radiation layer is preferably formed at least on a surface of the region not formed with the metal electrode layer. According to this structure, no current is supplied to the current path in the vicinity of the cavity facet, and hence a leakage current on the cavity facet can be reduced. The heat-radiation layer is formed on the region formed with no metal electrode layer, and hence heat generated in the cavity facet following light absorption can be effectively radiated outside through the heat-radiation layer.

In the aforementioned semiconductor laser device according to the first aspect, a refractive index of the current blocking layer is preferably smaller than a refractive index of the heat-radiation layer. According to this structure, light from the emission layer can be easily inhibited from spreading to a portion above the current path formed with the heat-radiation layer and stable light confinement can be performed by the current blocking layer.

In the aforementioned semiconductor laser device according to the first aspect, the heat-radiation layer is preferably made of any of semiconductor, dielectric or metal oxide. According to this structure, the heat-radiation layer facilitating heat radiation of the semiconductor laser device can be easily formed on the semiconductor device layer.

In the aforementioned semiconductor laser device according to the first aspect, the heat-radiation layer is preferably made of a single layer or a laminate of at least two layers made of at least any material selected from a group consisting of AlN, Si, SiN, SiC, Al₂O₃, ZnO and ITO. According to this structure, the heat-radiation layer having larger thermal conductivity than the current blocking layer made of dielectric generally having small thermal conductivity can be easily formed.

In the aforementioned semiconductor laser device according to the first aspect, the heat-radiation layer preferably includes a first heat-radiation layer and a second heat-radiation layer formed on a surface of the first heat-radiation layer on a side opposite to the semiconductor device layer, and the second heat-radiation layer is preferably an oxide film. According to this structure, the second heat-radiation layer made of an oxide film can protect the first heat-radiation layer from mechanical and thermal damages, and hence radiation performance of the first heat-radiation layer can be maintained.

The aforementioned semiconductor laser device according to the first aspect preferably further comprises a facet protective film formed on the cavity facet. According to this structure, the cavity facet can be further protected from a thermal damage.

In the aforementioned structure comprising the facet protective film, the facet protective film is preferably in contact with a surface of the heat-radiation layer located in the vicinity of the region formed with the cavity facet. According to this structure, heat generated from the current path in the vicinity of the cavity facet can be conducted not only to the heat-radiation layer in direct contact with the semiconductor device layer but also to the heat-radiation layer through the facet protective film formed on the cavity facet, and hence heat generated in the cavity facet can be reliably radiated.

The aforementioned structure comprising the facet protective film preferably further comprises a pad electrode formed on a region other than the vicinity of the region formed with the cavity facet of the semiconductor device layer, wherein a thickness of the facet protective film in contact with a surface of the heat-radiation layer is smaller than a thickness of the pad electrode. According to this structure, a current can be fed without blocking of the facet protective film in contact with the surface of the heat-radiation layer when arranging a side of the pad electrode to be in contact with the conductive layer and feeding a current.

A method of manufacturing a semiconductor laser device according to a second aspect of the present invention comprises steps of forming a semiconductor device layer having an emission layer and formed with a current path on a semiconductor layer in the vicinity of the emission layer, forming a current blocking layer on a region in the vicinity of the current path, and forming a heat-radiation layer having thermal conductivity larger than that of the current blocking layer at least in the vicinity of a region formed with a cavity facet of the semiconductor device layer and above the current path.

In the method of manufacturing a semiconductor laser device according to the second aspect of the present invention, as hereinabove described, the heat-radiation layer having thermal conductivity larger than that of the current blocking layer is formed at least in the vicinity of a region formed with the cavity facet of the semiconductor device layer and above the current path, heat generated on the region in the vicinity of the cavity facet in heat generated from the current path extending in a cavity direction can be effectively radiated outside through the heat-radiation layer formed above the current path when operating the semiconductor laser device. In other words, even when no pad electrode made of metal provided on the semiconductor laser device is formed on the region in the vicinity of the cavity facet, the aforementioned heat-radiation layer serves the function of facilitating heat radiation from the region in the vicinity of the cavity facet. Thus, the semiconductor laser device in which thermal degradation due to heat generated in the cavity facet is suppressed can be obtained. Further, the heat-radiation layer having the thermal conductivity larger than the thermal conductivity of the current blocking layer is formed, whereby heat generated in the current path on the region in the vicinity of the cavity facet can be radiated by preferentially conducting the heat to the heat-radiation layer having the thermal conductivity larger than that of the current blocking layer. The heat generated in the current path is effectively radiated from the heat-radiation layer, and hence the temperature increase of the current blocking layer is suppressed. Thus, the semiconductor laser device in which thermal degradation to the current blocking layer is reduced can be obtained.

The aforementioned method of manufacturing the semiconductor laser device according to the second aspect preferably further comprises a step of forming a pad electrode on a region other than the vicinity of the region formed with the cavity facet of the semiconductor device layer after the step of forming the heat-radiation layer, wherein the step of forming the pad electrode preferably includes a step of forming the pad electrode on a region formed with at least one of the current blocking layer and the heat-radiation layer. According to this structure, the pad electrode is away from the surface of the semiconductor device layer by the thickness of the current blocking layer or the heat-radiation layer and hence a parasitic capacitance (electrostatic capacitance) between the pad electrode and the semiconductor device layer can be reduced. Consequently, the semiconductor laser device in which high frequency operating characteristics are improved can be obtained.

In the aforementioned method of manufacturing a semiconductor laser device according to the second aspect preferably further comprises a step of forming the cavity facet on the semiconductor device layer by cleaving a portion of the semiconductor device layer corresponding to a region formed with the heat-radiation layer after the step of forming the heat-radiation layer. According to this structure, the cavity facet is formed on the region formed with the heat-radiation layer, and hence the semiconductor laser device, in which the cavity facet is inhibited from being excessively heated, due to effective heat radiation outside through the heat-radiation layer, can be obtained.

An optical pickup according to a third aspect of the present invention comprises a semiconductor laser device including a semiconductor device layer having an emission layer and formed with a current path on a semiconductor layer in the vicinity of the emission layer, a current blocking layer formed in the vicinity of the current path, and a heat-radiation layer formed to be provided at least in the vicinity of a region formed with a cavity facet of the semiconductor device layer and be located above the current path, and having thermal conductivity larger than that of the current blocking layer, an optical system controlling emitted light of the semiconductor laser device, and a light detection portion detecting the emitted light.

As hereinabove described, the optical pickup according to the third aspect of the present invention comprises the semiconductor laser device including the heat-radiation layer formed to be provided at least in the vicinity of the region formed with the cavity facet of the semiconductor device layer and be located above the current path, whereby heat generated on the region in the vicinity of the cavity facet in heat generated from the current path extending in a cavity direction of the laser device can be effectively radiated to the periphery of the laser device through the heat-radiation layer formed above the current path when operating the laser device constituting the optical pickup. Thus, the optical pickup in which thermal degradation of the semiconductor laser device is suppressed can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a schematic structure of a semiconductor laser device of the present invention;

FIG. 2 is a plan view showing a structure of a semiconductor laser device according to a first embodiment of the present invention;

FIG. 3 is a plan view showing a device structure in which a p-side pad electrode is removed from the semiconductor laser device according to the first embodiment shown in FIG. 2;

FIG. 4 is a sectional view taken along the line 1000-1000 in FIG. 2;

FIG. 5 is a sectional view taken along the line 1100-1100 in FIG. 2;

FIG. 6 is a sectional view taken along the line 1200-1200 in FIG. 2;

FIGS. 7 to 12 are diagrams for illustrating a manufacturing process of the semiconductor laser device according to the first embodiment shown in FIG. 2;

FIG. 13 is a sectional view showing a structure of a semiconductor laser device according to a modification of the first embodiment of the present invention;

FIGS. 14 to 16 are sectional views showing a structure of a semiconductor laser device according to a second embodiment of the present invention;

FIG. 17 and 18 are diagrams for illustrating a manufacturing process of the semiconductor laser device according to the second embodiment shown in FIG. 14;

FIG. 19 is a plan view showing a structure of a semiconductor laser device according to a third embodiment of the present invention;

FIG. 20 is a sectional view taken along the line 3000-3000 in FIG. 19;

FIG. 21 is a sectional view taken along the line 3100-3100 in FIG. 19;

FIG. 22 is a sectional view taken along the line 3200-3200 in FIG. 19;

FIG. 23 is a plan view showing a structure of a semiconductor laser device according to a fourth embodiment of the present invention;

FIG. 24 is a sectional view taken along the line 4100-4100 in FIG. 23;

FIG. 25 is a sectional view taken along the line 4200-4200 in FIG. 23;

FIG. 26 is a plan view showing a structure of a semiconductor laser device according to a fifth embodiment of the present invention;

FIG. 27 is a sectional view taken along the line 5000-5000 in FIG. 26;

FIG. 28 is a sectional view taken along the line 5100-5100 in FIG. 26;

FIG. 29 is a sectional view taken along the line 5200-5200 in FIG. 26;

FIG. 30 is a plan view showing a structure of a semiconductor laser device according to a sixth embodiment of the present invention;

FIG. 31 is a sectional view taken along the line 6000-6000 in FIG. 30;

FIG. 32 is a sectional view taken along the line 6200-6200 in FIG. 30;

FIG. 33 is a perspective view showing a structure of a ridge waveguide semiconductor laser device according to a seventh embodiment of the present invention;

FIG. 34 is a front elevational view showing the structure of the semiconductor laser device according to the seventh embodiment shown in FIG. 33;

FIG. 35 is a sectional view taken along the line 7000-7000 in FIG. 34;

FIGS. 36 to 38 are sectional views for illustrating a manufacturing process of the semiconductor laser device according to the seventh embodiment of the present invention;

FIGS. 39 to 41 are top plan views for illustrating a manufacturing process of the semiconductor laser device according to the seventh embodiment of the present invention;

FIG. 42 is a sectional view taken along the line 7100-7100 in FIG. 41;

FIG. 43 is a front elevational view showing a structure of a ridge waveguide semiconductor laser device according to a modification of the seventh embodiment of the present invention;

FIG. 44 is a sectional view taken along the line 7700-7700 in FIG. 43;

FIG. 45 is a perspective view showing a structure of a ridge waveguide semiconductor laser device according to an eighth embodiment of the present invention;

FIG. 46 is a sectional view taken along the line 8000-8000 in FIG. 45;

FIGS. 47 to 49 are top plan views for illustrating a manufacturing process of the semiconductor laser device according to the eighth embodiment of the present invention;

FIGS. 47 to 48 are top plans view for illustrating a manufacturing process of a semiconductor laser device according to the eighth embodiment of the present invention;

FIG. 50 is a perspective view showing a structure of a ridge waveguide semiconductor laser device according to a modification of the eighth embodiment of the present invention;

FIG. 51 is a perspective view showing a structure of a ridge waveguide semiconductor laser device according to a ninth embodiment of the present invention;

FIG. 52 is a sectional view taken along the line 9000-9000 in FIG. 51;

FIG. 53 is a perspective view showing a structure of a semiconductor laser device according to a tenth embodiment of the present invention;

FIG. 54 is a sectional view taken along the line 9500-9500 in FIG. 53;

FIG. 55 is an appearance perspective view showing a schematic structure of a laser apparatus mounted with a nitride-based semiconductor laser device according to an eleventh embodiment of the present invention;

FIG. 56 is a top plan view showing the laser apparatus mounted with the nitride-based semiconductor laser device according to the eleventh embodiment of the present invention, with a lid body of a can package thereof removed; and

FIG. 57 is a structure diagram of an optical pickup having the built-in laser apparatus.

### DESCRIPTION OF THE PREFERRED EMBODIMENTS

Embodiments of the present invention will be hereinafter described with reference to the drawings.

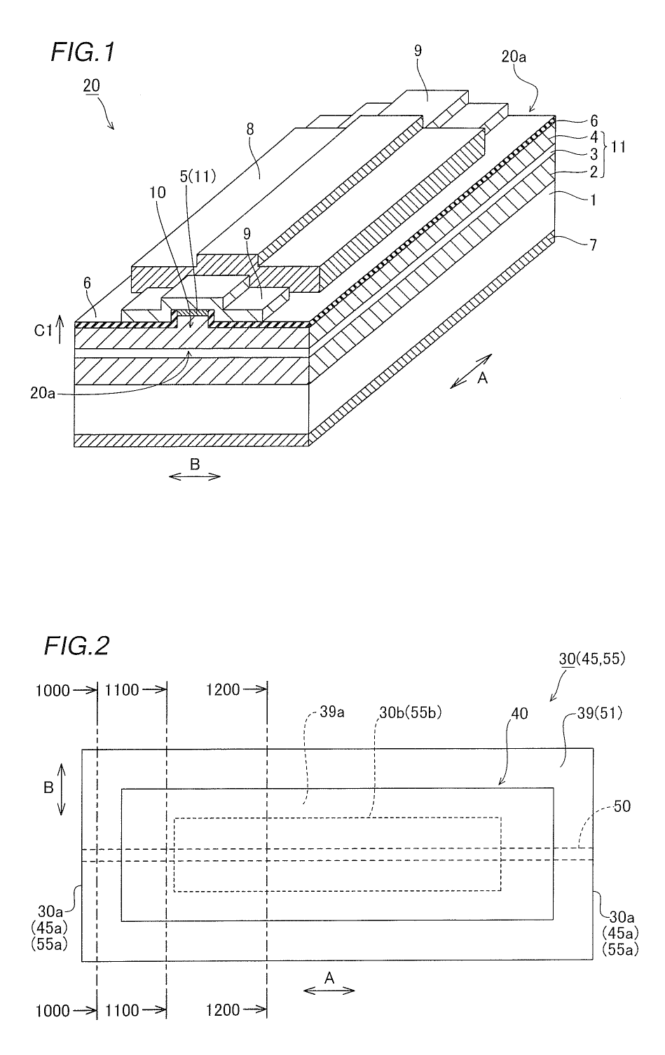

First, a structure of a semiconductor laser device 20 according to the present invention is schematically described with reference to FIG. 1, before specifically illustrating the embodiments of the present invention.

In the semiconductor laser device 20 according to the present invention, a first semiconductor layer 2, an active layer 3 and a second semiconductor layer 4 are successively stacked on a surface of a substrate 1, as shown in FIG. 1. The second semiconductor layer 4 is formed with a projecting portion protruding along arrow C1 and a planar portion extending to both sides (direction B) from the projecting portion as viewed from a cavity facets 20a. This projecting portion forms a ridge 10 extending in a direction (direction A) perpendicular to the cavity facets 20a in the form of a stripe. An optical waveguide is formed on a portion of the active layer 3 located on a lower portion of the ridge 10. The active layer 3 and the second semiconductor layer 4 are examples of the “emission layer” and the “semiconductor layer” in the present invention, respectively. The ridge 10 is an example of the “current path” in the present invention.

An ohmic electrode layer 5 is formed on the projecting portion of the second semiconductor layer 4. As shown in FIG. 1, a semiconductor device layer 11 is formed by the first semiconductor layer 2, the active layer 3 and the second semiconductor layer 4. A current blocking layer 6 made of SiO₂ is formed to cover an upper surface of the planar portion of the second semiconductor layer 4 and both side surfaces of the projecting portion of the second semiconductor layer 4 and the ohmic electrode layer 5. A first electrode 7 is formed on a lower surface of the substrate 1, and a second electrode 8 (pad electrode) extending in the direction A is formed to cover a prescribed region of the ohmic electrode layer 5 and the current blocking layer 6 except regions in the vicinity of a pair of the cavity facets 20a. The ohmic electrode layer 5 is an example of the “metal electrode layer” in the present invention, and the second electrode 8 is an example of the “pad electrode” in the present invention.

In the semiconductor laser device 20, thermal conductive films 9 are formed to cover prescribed regions of the ohmic electrode layer 5 and the adjacent current blocking layer 6 in the vicinity of the pair of cavity facets 20a. The thermal conductive films 9 are examples of the “radiation layer” in the present invention.

Each thermal conductive film 9 is made of a material having thermal conductivity larger than thermal conductivity (about 1.4 W/m·K) of the current blocking layer 6 made of SiO₂. More specifically, the thermal conductive film 9 is formed by at least one layer selected from a group consisting of AlN (about 150 W/m·K), Si (about 148 W/m·K), SiN (about 70 W/m·K), SiC (about 60 W/m·K), Al₂O₃ (about 32 W/m·K), ZnO (about 20 W/m·K), ZrO₂ (about 2 W/m·K) and ITO (about 8.2 W/m·K). Particularly, AlN and Si have large thermal conductivity.

The thermal conductive film 9 may have a single-layer structure or a multilayer structure. When the thermal conductive film 9 has the multilayer structure, thermal conductivity of the thermal conductive film (second insulating layer) on a side farther from the current blocking layer 6 is preferably rendered larger than the thermal conductivity of the thermal conductive film (first insulating layer) on a side closer to the current blocking layer 6. For example, when SiO₂ is employed for the aforementioned first insulating layer, SiN, Al₂O, diamond-like carbon (DLC) or the like can be employed as the second insulating layer in addition to AlN.

A refractive index of the aforementioned first insulating layer is preferably rendered smaller than a refractive index of the second insulating layer in order to easily performing more stable light confinement. For example, when SiO₂ is employed for the first insulating layer, SiN, AlN, Al₂O₃, DLC or the like is preferably employed as the second insulating layer. AlN, DLC or the like is preferably employed for the second insulating layer when the first insulating layer is Al₂O₃, while AlN, DLC or the like is preferably employed for the second insulating layer when the first insulating layer is ZrO₂. In the aforementioned case, when the first and second insulating layers are binary compounds containing the same element, the first insulating layer is made of an oxide and the second insulating layer is made of a nitride, so that the refractive index of the first insulating layer can be easily rendered smaller than the refractive index of the second insulating layer and adhesiveness between the first insulating layer and the second insulating layer can be improved.

When the current blocking layer 6 has a multilayer structure, a material having larger thermal conductivity than a material having the smallest thermal conductivity in the individually stacked materials of the current blocking layer is preferably employed for the thermal conductive film 9.

The thermal conductive films 9 has larger thermal conductivity than the current blocking layer 6, and hence has a function of effectively radiating heat generated in the vicinity of the cavity facets 20a during operating the laser device. SiO₂ employed as the current blocking layer of the semiconductor laser device generally has a thermal conductivity of about 1.4 w/m·K, and hence large radiation effects are expected so far as the thermal conductive film 9 has a thermal conductivity of at least about 5 W/m·K in this case. The thermal conductive film 9 may be electrically conductive. When the thermal conductive films 9 is electrically conductive, a current can be effectively injected also into the portions of the ridge 10 in the vicinity of the cavity facets 20a through the thermal conductive films 9 electrically connected to the second electrode 8. Thus, a threshold current of the laser device can be reduced. In particular, when ITO is employed for the thermal conductive films 9, electric conductivity of ITO is larger than that of the aforementioned material other than ITO, and hence a current can be effectively injected into the ridge 10 (ohmic electrode layer 5) in the vicinity of the cavity facets 20a. For example, other transparent conductive film such as ZnO doped with Al or Ga or SnO₂ doped with Sb or F (fluorine) may be employed in addition to ITO. These transparent conductive films have electrical resistivity of about 1×10⁻² Ωcm to 1×10⁻⁴ Ωcm.

The substrate 1 is formed by any one of a nitride-based semiconductor substrate having a wurtzite structure, an α-SiC substrate having a hexagonal structure and an α-SiC substrate having a rhombohedral structure. When the substrate 1 is a nitride-based semiconductor substrate having a wurtzite structure, the substrate 1 is made of GaN, AlN, InN, BN or TlN or alloyed semiconductor of these. A 4H—SiC substrate, 6H—SiC substrate or the like as an α-SiC substrate having a hexagonal structure or a rhombohedral structure may be employed for the substrate 1.

The substrate 1 may have n-type conductivity or alternatively may have p-type conductivity. When the substrate 1 has high resistivity, the first semiconductor layer 2 may be exposed on a region other than the substrate 1 and the first electrode 7 may be formed on the first semiconductor layer 2.

The first semiconductor layer 2, the active layer 3 and the second semiconductor layer 4 may be made of nitride-based semiconductor such as GaN, AlN, InN, BN or TlN or alloyed semiconductor of these. When the substrate 1 is electrically conductive, the first semiconductor layer 2 may be the same conductivity type as the substrate 1. The second semiconductor layer 4 has conductivity type different from the first semiconductor layer 2. The present invention may be applied to a semiconductor laser device other than a GaAs-based, InP-based, or ZnSe-based nitride-based semiconductor laser device.

The active layer 3 is formed by a single layer, a single quantum well (SQW) structure or a multiple quantum well (MQW) structure. When the active layer 3 is formed by a quantum well structure, GaInN can be particularly employed as a material of the well layer.

The first semiconductor layer 2 is made of material having a band gap larger than that of the active layer 3. An optical guide layer having an intermediate band gap between the band gap of the first semiconductor layer 2 and the band gap of the active layer 3 may be provided between the first semiconductor layer 2 and the active layer 3. A buffer layer may be provided between the substrate 1 and the first semiconductor layer 2. The second semiconductor layer 4 is made of a material having a larger band gap than the active layer 3. An optical guide layer having an intermediate band gap between the band gap of the second semiconductor layer 4 and the band gap of the active layer 3 may be provided between the second semiconductor layer 4 and the active layer 3. A contact layer may be provided on the second semiconductor layer 4 on a side opposite to the active layer 3. In this case, the contact layer is preferably formed by semiconductor having a smaller band gap than the second semiconductor layer 4. For example, the present invention may be applied to a semiconductor laser device having an embedded structure or an inner stripe structure.

The current blocking layer 6 is made of SiO₂, Al₂O₃, ZrO₂, TiO₂, Ta₂O₅ , La₂O₃, Si, AlN, AlGaN, SiN or the like. The current blocking layer 6 may be formed to have a multilayer structure by employing the aforementioned material. Alternatively, the semiconductor laser device according to the present invention may be gain-guiding semiconductor laser device.

In the semiconductor laser device 20 according to the present invention, as hereinabove described, the thermal conductive films 9 are formed to be located in the vicinity of the cavity facets 20a of the semiconductor device layer 11 above the current path (ridge 10), whereby heat generated on the regions in the vicinity of the cavity facets 20a in heat generated from the current path (ridge 10) extending in a cavity direction can be effectively radiated outside through the thermal conductive films 9 formed above the current path (ridge 10) when operating the semiconductor laser device 20. In other words, even when no second electrode 8 (pad electrode) made of metal is formed on the regions in the vicinity of the cavity facets 20a, the thermal conductive films 9 serve the function of facilitating heat radiation from the regions in the vicinity of the cavity facets 20a. Thus, thermal degradation on the semiconductor laser device 20 due to temperature increase in the cavity facets 20a can be suppressed.

In the semiconductor laser device 20 according to the present invention, the thermal conductive films 9 made of the materials having the larger thermal conductivity than the current blocking layer 6 formed in the vicinity of the ridge 10 are employed, whereby heat generated in the ridge 10 on the regions in the vicinity of the cavity facets 20a can be radiated by preferentially conducting the heat to the thermal conductive films 9 having the thermal conductivity larger than that of the current blocking layer 6. The heat of the ridge 10 is effectively radiated from the thermal conductive films 9, and hence the heat generated in the current blocking layer 6 is suppressed. Thus, thermal degradation to the current blocking layer 6 can be reduced.

In the semiconductor laser device 20 according to the present invention, the thermal conductive films 9 are formed to be in contact with the ohmic electrode layer 5 formed on the surface of the ridge 10, whereby heat generated from the ridge 10 can be effectively conducted to the thermal conductive films 9 through the ohmic electrode layer 5 made of metal formed on the surface of the ridge 10.

In the semiconductor laser device 20 according to the present invention, the thermal conductive films 9 are formed on the surface of the ohmic electrode layer 5 corresponding to regions formed with the ridge 10 (current path) in the vicinity of the regions formed with the cavity facets 20a, whereby heat generated from the ridge 10 (current path) in the vicinity of the cavity facets 20a can be effectively conducted to the thermal conductive films 9 through at least the ohmic electrode layer 5 formed on the surface of the ridge 10, and hence thermal degradation due to temperature increase in the cavity facets 20a can be easily suppressed also generally in the semiconductor laser device having a ridge structure employing the current blocking layer 6 made of dielectric having small thermal conductivity.

In the semiconductor laser device 20 according to the present invention, the thermal conductive films 9 are formed on the surface of the ohmic electrode layer 5 in the vicinity of the regions formed with the cavity facets 20a and on the current blocking layer 6 corresponding to the planar portion of the second semiconductor layer 4 other than the ridge 10, whereby heat generated from the ridge 10 (current path) in the vicinity of the cavity facets 20a can be radiated from the portions of the thermal conductive films 9 formed not only on the ohmic electrode layer 5 corresponding to the region formed with the ridge 10 but also on the current blocking layer 6 corresponding to the planar portion of the second semiconductor layer 4 other than the ridge 10, and hence heat generated on the regions in the vicinity of the cavity facets 20a can be reliably radiated outside.

Embodiments embodying the aforementioned concept of the present invention will be hereinafter described with reference to the drawings.

### First Embodiment

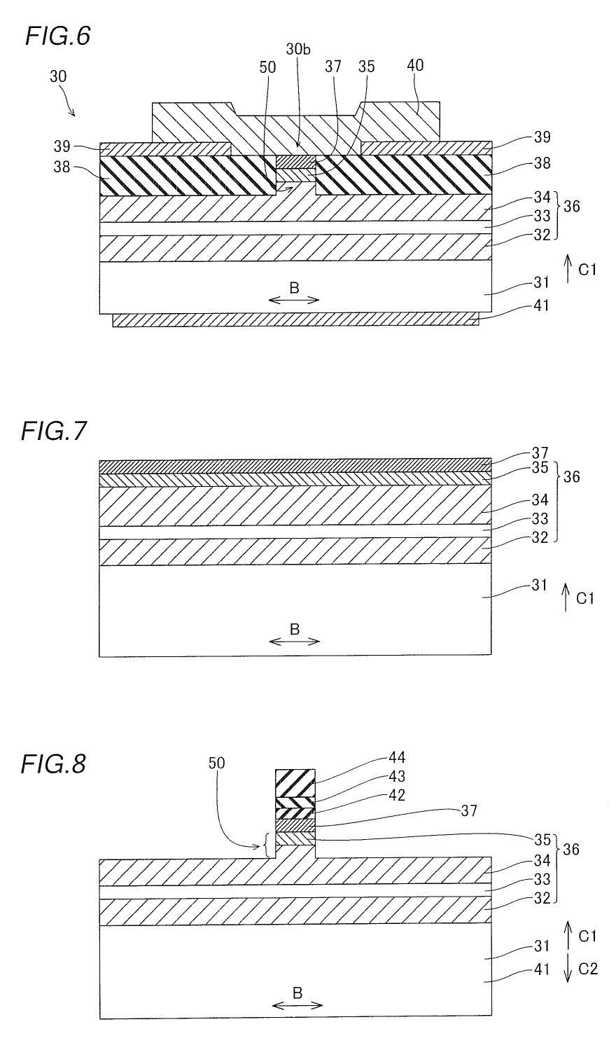

A structure of a semiconductor laser device 30 according to a first embodiment of the present invention will be now described with reference to FIGS. 2 to 6. FIG. 4 shows a cross section taken along the line 1000-1000 in FIG. 2, and FIG. 5 shows a cross section taken along the line 1100-1100 in FIG. 2. FIG. 6 shows a cross section taken along the line 1200-1200 in FIG. 2.

In the semiconductor laser device 30 according to the first embodiment of the present invention, an n-type cladding layer 32 is formed on an n-type GaN substrate 31, shown in FIG. 4. An active layer 33 having an MQW structure in which well layers and barrier layers are alternately stacked is formed on the n-type cladding layer 32. A p-type cladding layer 34 having a planar portion and a projecting portion with a width of about 1 μm to about 2 μm, extending in a direction A (see FIG. 2) and protruding upward (along arrow C1) from a substantially central portion of the planar portion is formed on the active layer 33. The active layer 33 and the p-type cladding layer 34 are examples of the “emission layer” and the “semiconductor layer” in the present invention respectively.

As shown in FIG. 4, a p-side contact layer 35 is formed on the projecting portion of the p-type cladding layer 34. The n-type cladding layer 32, the active layer 33, the p-type cladding layer 34 and the p-side contact layer 35 forms a semiconductor device layer 36. The p-side contact layer 35 is an example of the “semiconductor layer” in the present invention. A p-side ohmic electrode 37 is formed on the p-side contact layer 35. According to the first embodiment, the projecting portion of the p-type cladding layer 34 and the p-side contact layer 35 form a ridge 50 extending in a cavity direction (direction A in FIG. 2) of the semiconductor laser device 30 in the form of a stripe. This ridge 50 forms an optical waveguide structure. The ridge 50 is an example of the “current path” in the present invention, and the p-side ohmic electrode 37 is an example of the “metal electrode layer” in the present invention.

As shown in FIG. 4, a current blocking layer 38 made of SiO₂ having a thickness of about 200 nm is formed to cover an upper surface of planar portion except the projecting portion of the p-type cladding layer 34 and both side surfaces of the ridge 50 (including the projecting portion).

According to the first embodiment, a thermal conductive film 39 made of Si, having a thickness of about 300 nm is formed on a prescribed region from cavity facets 30a (see FIG. 2) toward a center of the semiconductor laser device 30 along the direction A to cover upper surfaces of the p-side ohmic electrode 37 and the current blocking layer 38, as shown in FIG. 4. The thermal conductive film 39 is an example of the “radiation layer” in the present invention.

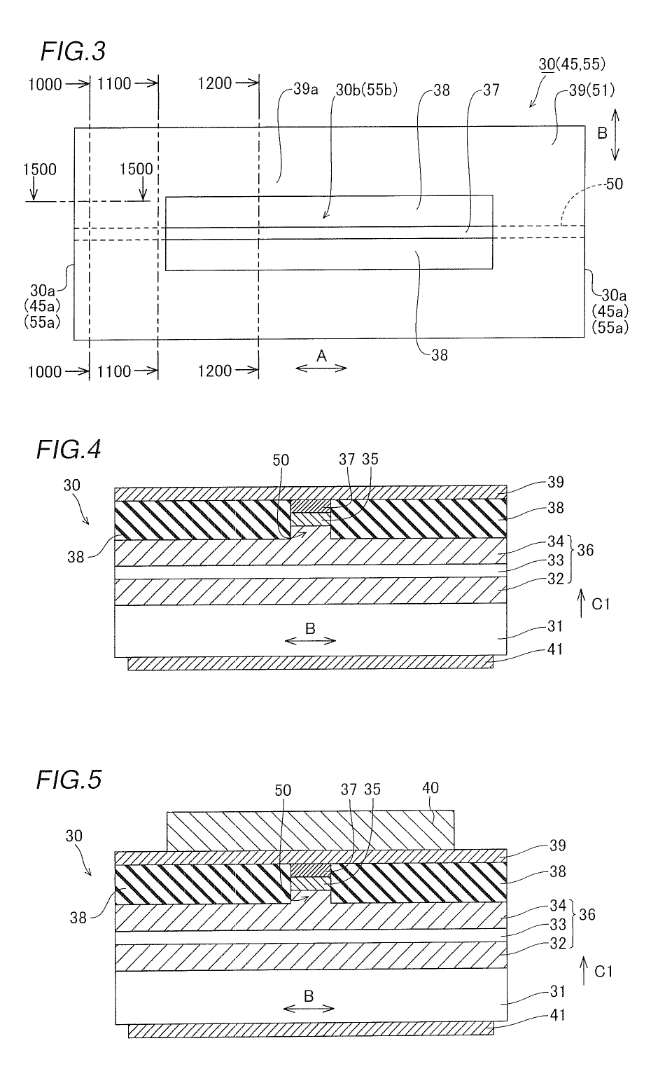

As shown in FIGS. 2 and 3, the thermal conductive film 39 is formed to cover the prescribed region (upper surface of the device except a device central region 30b in FIG. 3) inward from regions in the vicinity of a pair of the cavity facets 30a of the semiconductor laser device 30 and ends in a width direction (direction B) of the device along the direction A in plan view. Thus, heat of the ridge 50 in the vicinity of the regions of the cavity facets 30a can be diffused toward a center of the semiconductor laser device 30 in the direction A through the thermal conductive film 39.

According to the first embodiment, a p-side pad electrode 40 made of Au, having a thickness of about 500 nm, covering a partial region 39a of the thermal conductive film 39, and the device central region 30b formed with no thermal conductive film 39 and having a rectangular shape is formed as shown in FIG. 2. The p-side pad electrode 40 is an example of the “pad electrode” in the present invention. In FIG. 2, the rectangular region enclosed with a broken line is shown as the device central region 30b formed with no thermal conductive film 39.

When the semiconductor laser device 30 is viewed in a sectional manner, the p-side pad electrode 40 is formed to cover a prescribed region on an upper surface of the thermal conductive film 39 at a position shown in FIG. 5 (cross section taken along the line 1100-1100 in FIG. 2). At a position shown in FIG. 6 (cross section taken along the line 1200-1200 in FIG. 2), the p-side pad electrode 40 is formed to cover the prescribed region of the upper surface of the thermal conductive film 39 and to be in direct contact with and cover an upper surface of the p-side ohmic electrode 37 formed on the substantial central portion in the device width direction (direction B) and an upper surface of the current blocking layer 38 adjacent to both sides of the p-side ohmic electrode 37 (device central region 30b in FIG. 2). Therefore, the p-side pad electrode 40 is formed only on the region 39a other than the regions in the vicinity of the cavity facets 30a to be in contact with the thermal conductive film 39, as shown in FIG. 2. Thus, the p-side pad electrode 40 absorbs heat generated in the ridge 50 on the device central region 30b and also absorbs heat diffused to the thermal conductive film 39 (region 39a) from the vicinity of the cavity facets 30a.

As shown in FIGS. 4 to 6, an n-side electrode 41 is formed on a lower surface of an n-type GaN substrate 31.

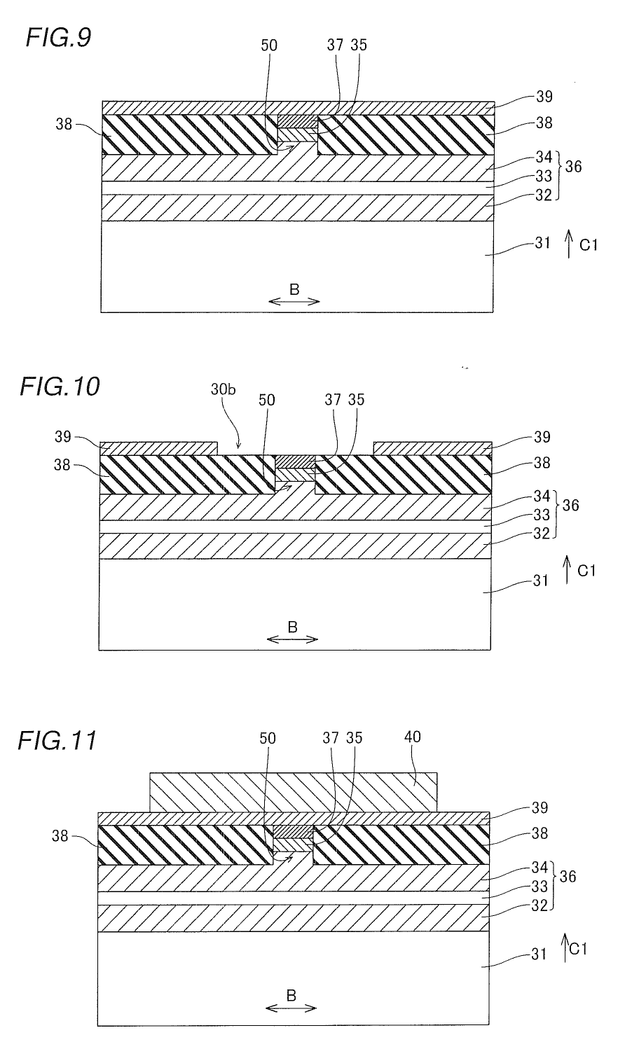

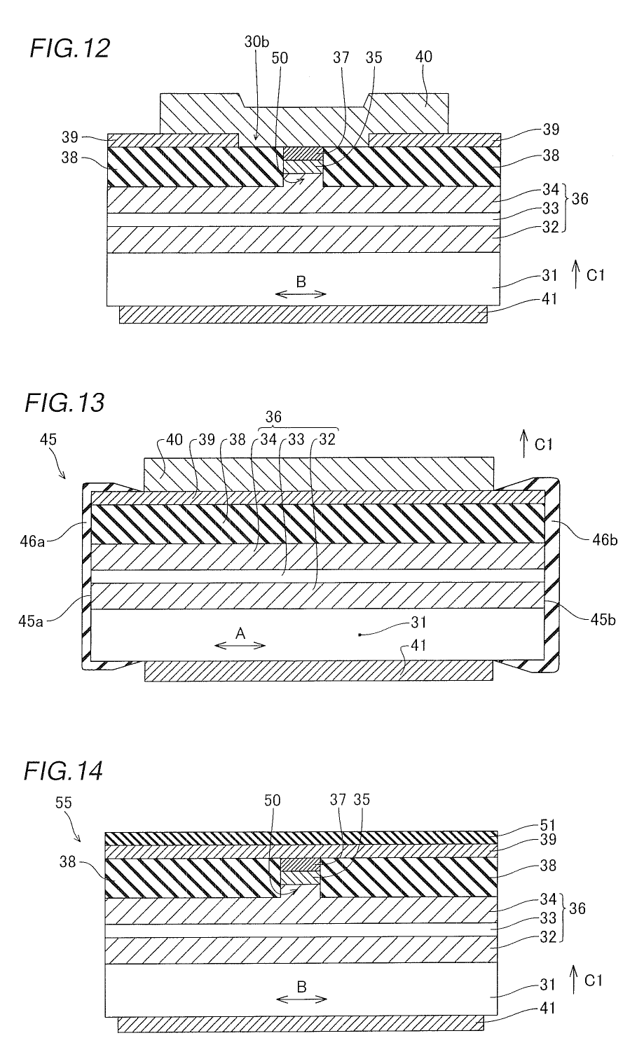

A manufacturing process for the semiconductor laser device 30 according to the first embodiment will be now described with reference to FIGS. 2, 3 and 7 to 12. FIG. 9 shows a cross section in a manufacturing process for the semiconductor laser device 30 at the position taken along the line 1000-1000 in FIG. 2. FIGS. 10 and 12 are cross sections in a manufacturing process for the semiconductor laser device 30 at the position taken along the line 1200-1200 in FIG. 2 and FIG. 11 shows a cross section in a manufacturing process for the semiconductor laser device 30 at the position taken along the line 1100-1100 in FIG. 2.

In the manufacturing process for the semiconductor laser device 30 according to the first embodiment, the n-type cladding layer 32, the active layer 33, the p-type cladding layer 34 and the p-side contact layer 35 are successively stacked on the upper surface of the n-type GaN substrate 31 by metal organic chemical vapor deposition (MOCVD), thereby forming a semiconductor device layer 36, as shown in FIG. 7. Thereafter, the p-side ohmic electrode 37 is formed on the overall upper surface of the p-side contact layer 35.

Thereafter, a spacer layer 42 made of Ge having a thickness of about 100 nm and a mask layer 43 made of SiO₂ are formed on an overall upper surface of the p-side ohmic electrode 37, as shown in FIG. 8. A resist (resist pattern) 44 is formed on an upper surface of the mask layer 43 by photolithography. Thereafter, the resist 44 is employed as a mask for patterning the mask layer 43, the spacer layer 42, the p-side ohmic electrode 37, the p-side contact layer 35 of the semiconductor device layer 36, the partial p-type cladding layer 34 by dry etching from the mask layer 43 to a position of a prescribed depth of the p-type cladding layer 34 along arrow C2, thereby forming the ridge 50 having a convex shape along arrow C1 from the p-type cladding layer 34. At this time, the p-side ohmic electrode 37 is formed to have the same width (direction B) as the ridge 50 in addition to the p-side contact layer 35.

The current blocking layer 38 is formed to cover the upper surface of the planar portion except the projecting portion of the p-type cladding layer 34 and the both side surfaces of the ridge 50 (including the portions of the p-side ohmic electrode 37) by plasma activated chemical vapor deposition (PCVD), as shown in FIG. 9. Then the spacer layer 42, the mask layer 43 and the resist 44 remained on the ridge 50 are removed by wet etching by a phosphoric acid etching solution.

The thermal conductive film 39 made of Si is formed, as shown in FIGS. 9 and 10. At this time, in the manufacturing process of the first embodiment, the thermal conductive film 39 is formed to cover the overall upper surfaces of the p-side ohmic electrode 37 and the current blocking layer 38 in the vicinity of the regions of the cavity facets 30a (see FIG. 2) of the semiconductor laser device 30, as shown in FIG. 9. As shown in FIG. 10, on the region other than the regions in the vicinity of the cavity facets 30a (see FIG. 2) of the semiconductor laser device 30, the thermal conductive film 39 is formed to cover only the prescribed region, from the ends in the direction B toward the inside of the device, of the current blocking layer 38. Thus, the upper surface of the p-side ohmic electrode 37 and the current blocking layer 38 are exposed without forming the thermal conductive film 39 on the device central region 30b in the direction B, as shown in FIG. 3.

The p-side pad electrode 40 is formed by vacuum evaporation, as shown in FIGS. 11 and 12. At this time, the p-side pad electrode 40 is formed on the thermal conductive film 39 to be continuously in contact with the thermal conductive film 39 in the direction B in FIG. 11, while the p-side pad electrode 40 is formed on the p-side ohmic electrode 37 and the current blocking layer 38 at the device central region 30b to be in direct contact with the p-side ohmic electrode 37 and the current blocking layer 38 on the device central region 30b in addition to the thermal conductive film 39 in FIG. 12. Therefore, on the device central region 30b, the upper surface of the p-side pad electrode 40 is recessed in a substantially concave shape by a thickness of the current blocking layer 38, as shown in FIG. 12. The p-side pad electrode 40 is formed to be in contact with the thermal conductive film 39 only on the region 39a other than the regions in the vicinity of the cavity facets 30a as shown in FIG. 2.

Then, a lower surface of the n-type GaN substrate 31 is so polished that the n-type GaN substrate 31 has a prescribed thickness and the n-side electrode 41 is thereafter formed on the lower surface of the n-type GaN substrate 31 by vacuum evaporation, as shown in FIG. 12.

Finally, the cavity facets 30a (see FIG. 2) are formed by cleavage and the device division (singulation) is performed along the cavity direction (direction A). Thus, the semiconductor laser device 30 according to the first embodiment shown in FIG. 2 is formed.

According to the first embodiment, as hereinabove described, the thermal conductive film 39 is formed to be located in the vicinity of the cavity facets 30a of the semiconductor device layer 36 above the ridge 50, whereby heat generated on the regions in the vicinity of the cavity facets 30a in heat generated from the ridge 50 extending in the cavity direction can be effectively radiated outside through the thermal conductive film 39 formed above the ridge 50 when operating the semiconductor laser device 30. In other words, even when the p-side pad electrode 40 made of metal is not formed on the regions in the vicinity of the cavity facets 30a, the thermal conductive films 39 serve the function of facilitating heat radiation from the regions in the vicinity of the cavity facets 30a. Thus, thermal degradation due to heat generated in the cavity facets 30a of the semiconductor laser device 30 can be suppressed.

According to the first embodiment, the thermal conductive film 39 made of Si, having the thermal conductivity (about 148 W/m·K) larger than the thermal conductivity (about 1.4 W/m·K) of the current blocking layer 38 made of SiO₂, formed in the vicinity of the ridge 50 are employed, whereby heat generated in the ridge 50 on the regions in the vicinity of the cavity facets 30a can be radiated by preferentially conducting the heat to the thermal conductive films 39 having the thermal conductivity larger than that of the current blocking layer 38. The heat of the ridge 50 is effectively radiated from the thermal conductive film 39, and hence the heat generated in the current blocking layer 38 is suppressed. Thus, thermal degradation to the current blocking layer 38 can be reduced.

According to the first embodiment, the thermal conductive film 39 is arranged above the ridge 50 on the region formed with no p-side pad electrode 40, whereby the thermal conductive film 39 can reliably absorb heat generated from the ridge 50 on the regions in the vicinity of the cavity facets 30a, even when the p-side pad electrode 40 made of Au is not formed on the region in the vicinity of the cavity facets 30a.

According to the first embodiment, the p-side pad electrode 40 is formed on the regions formed with the current blocking layer 38 and thermal conductive film 39 respectively, whereby the p-side pad electrode 40 can be away from the surface of the semiconductor device layer 36 along arrow C1 by the thickness of the current blocking layer 38 or the thermal conductive film 39 and hence a parasitic capacitance (electrostatic capacitance) between the p-side pad electrode 40 and the semiconductor device layer 36 can be reduced. Consequently, high frequency operating characteristics of the semiconductor laser device 30 can be improved.

According to the first embodiment, the p-side pad electrode 40 is in contact with the thermal conductive film 39 on the region other than the vicinity of the regions formed with the cavity facets 30a, whereby heat generated on the regions in the vicinity of the cavity facets 30a can be effectively radiated outside not only through the thermal conductive film 39 but also through the p-side pad electrode 40 in contact with the thermal conductive film 39.

According to the first embodiment, the semiconductor device layer 36 has a ridge structure in which the current blocking layer 38 covers side portions of the ridge 50 (current path), whereby thermal degradation due to heat generated in the cavity facets 30a can be easily suppressed by the thermal conductive film 39 having larger thermal conductivity than the current blocking layer 38 also in the semiconductor laser device 30 having the ridge structure employing the current blocking layer 38 made of dielectric having small thermal conductivity.

According to the first embodiment, the thermal conductive film 39 is formed to be in contact with the p-side ohmic electrode 37 formed on the surface of the ridge 50, whereby heat generated from the ridge 50 can be effectively conducted to the thermal conductive film 39 through the p-side ohmic electrode 37 made of metal formed on the surface of the ridge 50.

According to the first embodiment, the thermal conductive film 39 having thermal conductivity of at least 5 W/m·K is employed, whereby heat generated in the vicinity of the cavity facets 30a can be easily radiated by the thermal conductive film 39 having much larger thermal conductivity than the current blocking layer 38 of dielectric having small thermal conductivity (about 1.4 W/m·K).

According to the first embodiment, the thermal conductive film 39 is formed on the surface of the p-side ohmic electrode 37 of the upper portion of the region formed with the ridge 50 (current path) in the vicinity of the regions formed with the cavity facets 30a, whereby heat generated from the ridge 50 (current path) in the vicinity of the cavity facets 30a can be effectively conducted to the thermal conductive film 39 through at least the p-side ohmic electrode 37 formed on the surface of the ridge 50.

According to the first embodiment, the thermal conductive film 39 made of Si is employed as the “radiation layer” in the present invention, whereby the heat-radiation layer facilitating heat radiation of the semiconductor laser device 30 can be easily formed on the semiconductor device layer 36.

### Modification of First Embodiment

Referring to FIGS. 3 and 13, a facet protective film 46a is formed on a cavity facet 45a in a semiconductor laser device 45 according to a modification of the first embodiment, dissimilarly to the aforementioned first embodiment. FIG. 13 shows a cross section taken along the line 1500-1500 in FIG. 3.

According to the modification of the first embodiment, the facet protective film 46a made of an AlN film having a thickness of about 10 nm and an Al₂O₃ having a thickness of about 80 nm successively from the cavity facet 45a is formed on the cavity facet 45a on a light emitting side, as shown in FIG. 13. A facet protective film 46b made of a SiO₂/ZrO₂ multiply-stacked layer, having a total thickness of about 600 nm is formed on a cavity facet 45b on a side opposite to the cavity facet 45a on the light emitting side. The facet protective films 46a and 46b are formed on upper ends (along arrow C1) of the cavity facets 45a and 45b respectively to be in contact with the thermal conductive film 39 by covering side surfaces and a partial upper surface of the thermal conductive film 39. Therefore, on the regions in the vicinity of the facet protective films 46a and 46b, heat generated in a ridge 50 (see FIG. 3) is radiated to the thermal conductive film 39 above the ridge 50 not only through the p-side ohmic electrode 37 (see FIG. 3) but also through the portions, in contact with the thermal conductive film 39, of the facet protective films 46a and 46b.

In this case, the facet protective films 46a and 46b formed on the upper surface of the thermal conductive film 39 have maximum thicknesses of about 10 nm and about 50 nm respectively, and are formed with thicknesses smaller than a thickness of a p-side pad electrode 40 or an n-side electrode 41. Thus, a current can be fed without being inhibited by the facet protective film 46a or 46b when assembling or conducting a current-feeding test in a chip state. The remaining structure and manufacturing process of the modification of the first embodiment are similar to those of the aforementioned first embodiment, except that the facet protective film 46a (46b) is formed on the cavity facet 45a (45b) to be in contact with the thermal conductive film 39.

According to the modification of the first embodiment, as hereinabove described, the facet protective film 46a formed on the cavity facet 45a is in contact with the surface of the thermal conductive film 39 located in the vicinity of a region formed with the cavity facet 45a, whereby heat generated from a current path (ridge 50) in the vicinity of the cavity facet 45a can be conducted not only to the thermal conductive film 39 in direct contact with the semiconductor device layer 36 but also to the thermal conductive film 39 from the semiconductor layer 36 through the facet protective film 46a formed on the cavity facet 45a, and hence heat generated in the cavity facet 45a can be reliably radiated. The remaining effects of the modification of the first embodiment are similar to those of the aforementioned first embodiment.

### Second Embodiment

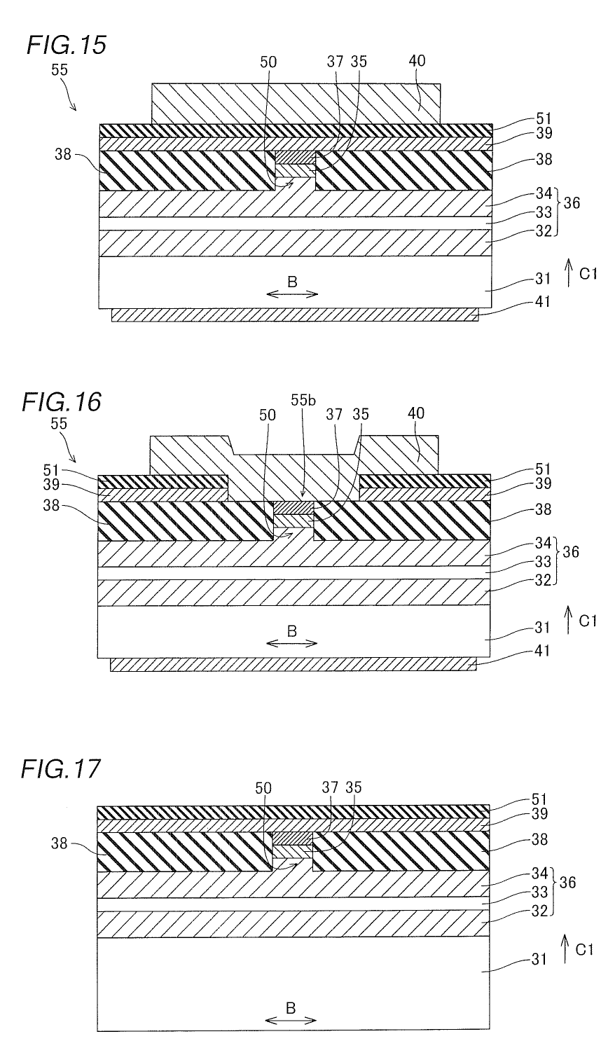

Referring to FIGS. 2 and 14 to 16, a thermal conductive film 51 made of a material different from a thermal conductive film 39 is further formed on a surface of the thermal conductive film 39 in a semiconductor laser device 55 according to a second embodiment, dissimilarly to the aforementioned first embodiment. FIG. 14 shows a cross section taken along the line 1000-1000 in FIG. 2, and FIG. 15 shows a cross section taken along the line 1100-1100 in FIG. 2. FIG. 16 shows a cross section taken along the line 1200-1200 in FIG. 2.

According to the second embodiment, the thermal conductive film 51 made of SiO₂ is formed on the surface of the thermal conductive film 39 made of Si, as shown in FIGS. 14 to 16. The thermal conductive film 39 has a thickness of about 150 nm and the thermal conductive film 51 has a thickness of about 100 nm. Therefore, the p-side pad electrode 40 is formed to continuously cover the thermal conductive film 51 in a direction B at a position shown in FIG. 15 (cross section taken along the line 1100-1100 in FIG. 2). Thus, heat of a ridge 50 on regions in the vicinity of cavity facets 55a can be diffused toward a center of the semiconductor laser device 55 in a direction A through the thermal conductive films 39 and 51. The thermal conductive films 39 and 51 are examples of the “first heat-radiation layer” and the “second heat-radiation layer” in the present invention respectively. The thermal conductive film 51 is an example of the “oxide film” in the present invention.

At a position (cross section taken along the line 1200-1200 in FIG. 2) shown in FIG. 16, the p-side pad electrode 40 is formed on a p-side ohmic electrode 37 and a current blocking layer 38 at a device central region 55b to be in direct contact with the p-side ohmic electrode 37 and the current blocking layer 38 on a device central region 55b in addition to the upper surface of the thermal conductive film 51. Thus, the p-side pad electrode 40 absorbs heat of the ridge 50 on the device central region 55b and also absorbs heat diffused to the thermal conductive film 39 (region 39a) and the thermal conductive film 51 from the vicinity of the cavity facets 55a.

The remaining structure of the semiconductor laser device 55 according to the second embodiment is similar to that of the aforementioned first embodiment.

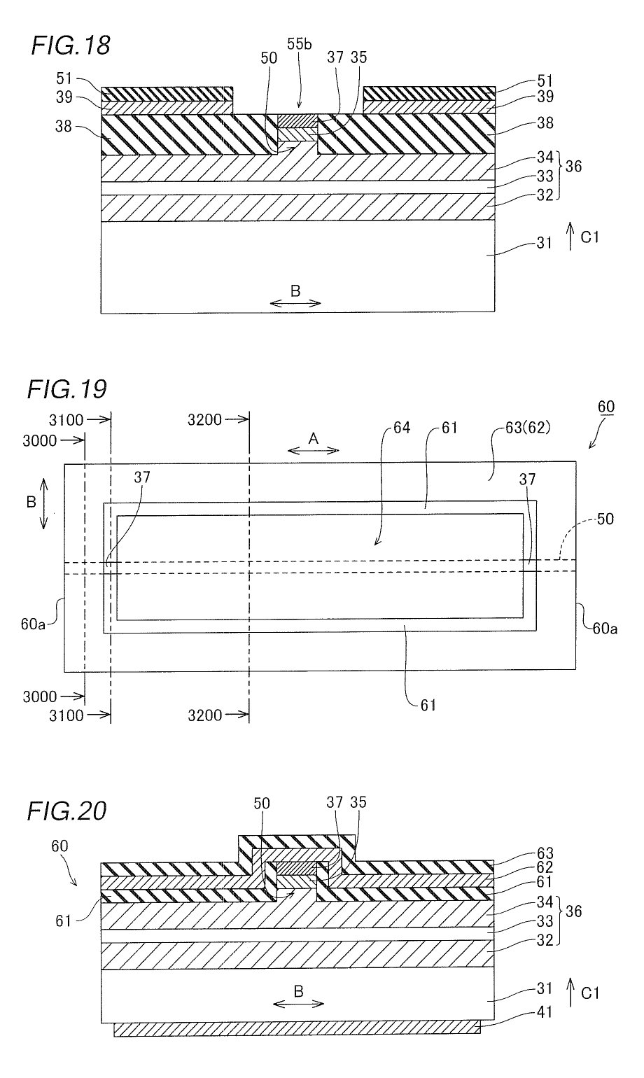

A manufacturing process for the semiconductor laser device 55 according to the second embodiment will be now described with reference to FIGS. 8 and 14 to 18. FIG. 17 shows a cross section in a manufacturing process for the semiconductor laser device 55 at the position taken along the line 1000-1000 in FIG. 2, and FIG. 18 is a cross section in a manufacturing process for the semiconductor laser device 55 at the position taken along the line 1200-1200 in FIG. 2.

In the manufacturing process for the semiconductor laser device 55 according to the second embodiment, the ridge 50 is formed on a semiconductor device layer through a manufacturing process similar to that of the aforementioned first embodiment, as shown in FIG. 8.

Thereafter, the thermal conductive film 39 made of Si is formed as shown in FIGS. 17 and 18. Then the thermal conductive film 51 made of SiO₂ is formed to cover the thermal conductive film 39. The remaining manufacturing process of the second embodiment is similar to that of the aforementioned first embodiment.

According to the second embodiment, as hereinabove described, the thermal conductive film 51 made of SiO₂ is formed on the thermal conductive film 39 in addition to the thermal conductive film 39 made of Si, whereby heat generated in the ridge 50 on the regions in the vicinity of the cavity facets 55a (see FIG. 2) can be effectively diffused to the p-side pad electrode 40 (see FIG. 15) not only through the thermal conductive film 39 but also through the thermal conductive film 51 (see FIG. 14).

According to the second embodiment, the thermal conductive film 51 is made of the oxide film, whereby the thermal conductive film 51 can protect the thermal conductive film 39 from mechanical and thermal damages, and hence radiation performance of the thermal conductive film 39 can be maintained. The remaining effects of the second embodiment is similar to that of the aforementioned first embodiment.

### Third Embodiment

Referring to FIGS. 19 to 22, a current blocking layer 61 having a prescribed thickness is formed on side surfaces of a ridge 50 and a planar portion of a p-type cladding layer 34 in a semiconductor laser device 60 according to a third embodiment, dissimilarly to the aforementioned second embodiment.

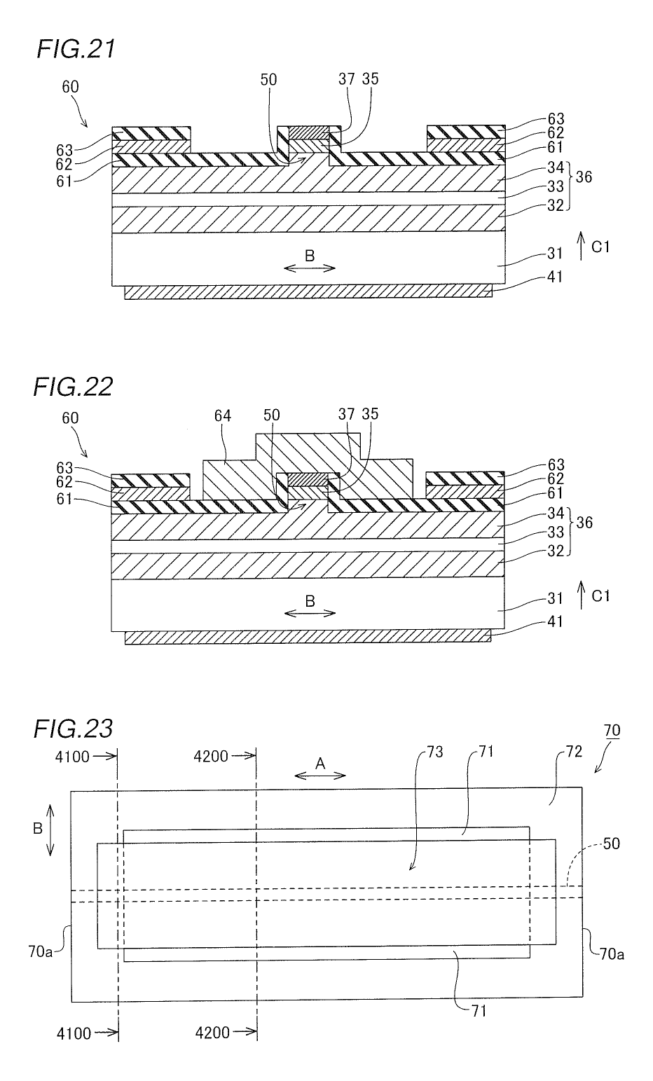

FIG. 20 shows a cross section taken along the line 3000-3000 in FIG. 19, and FIG. 21 shows a cross section taken along the line 3100-3100 in FIG. 19. FIG. 22 shows a cross section taken along the line 3200-3200 in FIG. 19.

According to the third embodiment, the current blocking layer 61 made of SiO₂, having the prescribed thickness is formed on the side surfaces of the ridge 50 and the planar portion of the p-type cladding layer 34 as shown in FIGS. 20 to 22. Therefore, at a position (cross section taken along the line 3000-3000 in FIG. 19) shown in FIG. 20, a thermal conductive film 62 made of Si and a thermal conductive film 63 made of SiO₂ are formed to protrude in a convex shape on the portion of the ridge 50. The thermal conductive films 62 and 63 have thicknesses of about 150 nm. Thus, heat of the ridge 50 on regions in the vicinity of the cavity facets 60a can be diffused toward a center of the semiconductor laser device 60 in a direction A through the thermal conductive films 62 and 63. According to the third embodiment, the thermal conductive films 62 and 63 are examples of the “first heat-radiation layer” and the “second heat-radiation layer” in the present invention respectively. The thermal conductive film 63 is an example of the “oxide film” in the present invention.

According to the third embodiment, a p-side pad electrode 64 is formed on a central region of the device except the regions in the vicinity of the cavity facets 60a (see FIG. 19) of the semiconductor laser device 60 along a shape of the ridge 50 to extend in the direction A (see FIG. 19), as shown in FIG. 22. The p-side pad electrode 64 is not in contact with the thermal conductive films 62 and 63 at a position (cross section taken along the line 3200-3200 in FIG. 19) shown in FIG. 22. Therefore, the p-side pad electrode 64 is formed in a state of being enclosed with the thermal conductive films 62 and 63 at prescribed interval, as shown in FIG. 19. In other words, the p-side ohmic electrode 37 of the ridge 50 is exposed outside at a position (cross section taken along the line 3100-3100 in FIG. 19) shown in FIG. 21. The p-side pad electrode 64 is an example of the “pad electrode” in the present invention.

As shown in FIGS. 19 and 20, the thermal conductive films 62 and 63 cover the regions in the vicinity of the cavity facets 60a (see FIG. 19) of the semiconductor laser device 60, and hence heat is excellently radiated from the ridge 50 similarly to the aforementioned first and second embodiment.

The remaining structure and manufacturing process of the semiconductor laser device 60 according to the third embodiment are similar to those of the aforementioned second embodiment.

According to the third embodiment, as hereinabove described, the thermal conductive film 62 is formed on the surface of the p-side ohmic electrode 37 in the vicinity of the regions formed with the cavity facets 60a and on the current blocking layer 61 corresponding to the planar portion of the semiconductor device layer 36 other than the ridge 50, whereby heat generated from the ridge 50 (current path) in the vicinity of the cavity facets 60a can be radiated not only from the p-side ohmic electrode 37 corresponding to the region formed with the ridge 50 but also from the portion of the thermal conductive film 62 (63) formed on the current blocking layer 61 corresponding to the planar portion of the semiconductor device layer 36 except the ridge 50, and hence heat generated on the regions in the vicinity of the cavity facets 60a can be reliably radiated outside. The remaining effects of the third embodiment are similar to those of the aforementioned second embodiment.

### Fourth Embodiment

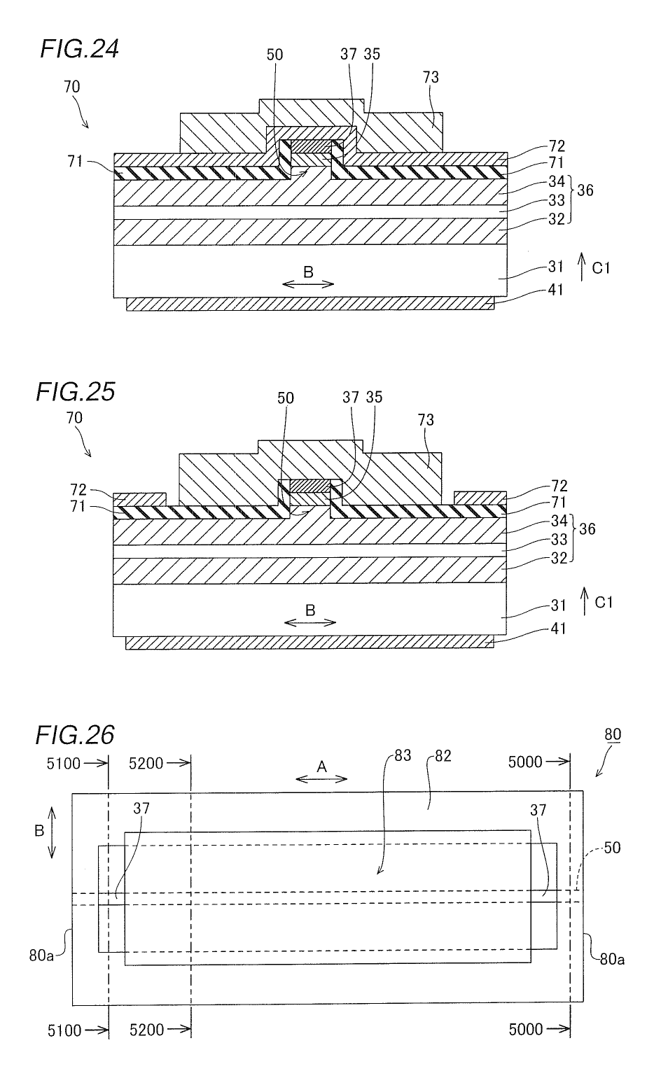

Referring to FIGS. 23 to 25, a thermal conductive film 72 and a p-side pad electrode 73 on an upper portion of a ridge 50 are formed to be in contact with each other on regions in the vicinity of cavity facets 70a in a semiconductor laser device 70 according to a fourth embodiment, dissimilarly to the aforementioned third embodiment. FIG. 24 shows a cross section taken along the line 4100-4100 in FIG. 23. FIG. 25 shows a cross section taken along the line 4200-4200 in FIG. 23.

According to the fourth embodiment, a current blocking layer 71 made of SiO₂, having a prescribed thickness is formed on side surface of a ridge 50 and a planar portion of a p-type cladding layer 34, as shown in FIGS. 24 and 25. Therefore, at a position (cross section taken along the line 4100-4100 in FIG. 23) shown in FIG. 24, the thermal conductive film 72 made of Si, having a thickness of about 50 nm is formed to protrude in a convex shape on a portion of the ridge 50. The thermal conductive film 72 is an example of the “radiation layer” in the present invention.

According to the fourth embodiment, the p-side pad electrode 73 is formed along a shape of the ridge 50 as shown in FIG. 24. The p-side pad electrode 73 is formed to be in contact with the thermal conductive film 72 on the region in the vicinity of the cavity facets 70a, as shown in FIG. 23. The p-side pad electrode 73 is an example of the “pad electrode” in the present invention.

The p-side pad electrode 73 is not in contact with the thermal conductive film 72 at a position (cross section taken along the line 4200-4200 in FIG. 23) shown in FIG. 25. Therefore, heat radiation from the ridge 50 on a central region in a cavity direction of the semiconductor laser device 70 is excellently performed through the p-side pad electrode 73 in direct contact with the p-side ohmic electrode 37.

The remaining structure and manufacturing process of the semiconductor laser device 70 according to the fourth embodiment are similar to those of the aforementioned third embodiment.

According to the fourth embodiment, as hereinabove described, the p-side pad electrode 73 is formed along the shape of the ridge 50 (convex shape) to be in contact with the thermal conductive film 72 on the regions in the vicinity of the cavity facets 70a, whereby heat generated in the ridge 50 on the regions in the vicinity of the cavity facets 70a of the semiconductor laser device 70 can be excellently conducted to the p-side pad electrode 73 through the conductive film 72 and radiated. The remaining effects of the fourth embodiment are similar to those of the aforementioned first embodiment.

### Fifth Embodiment

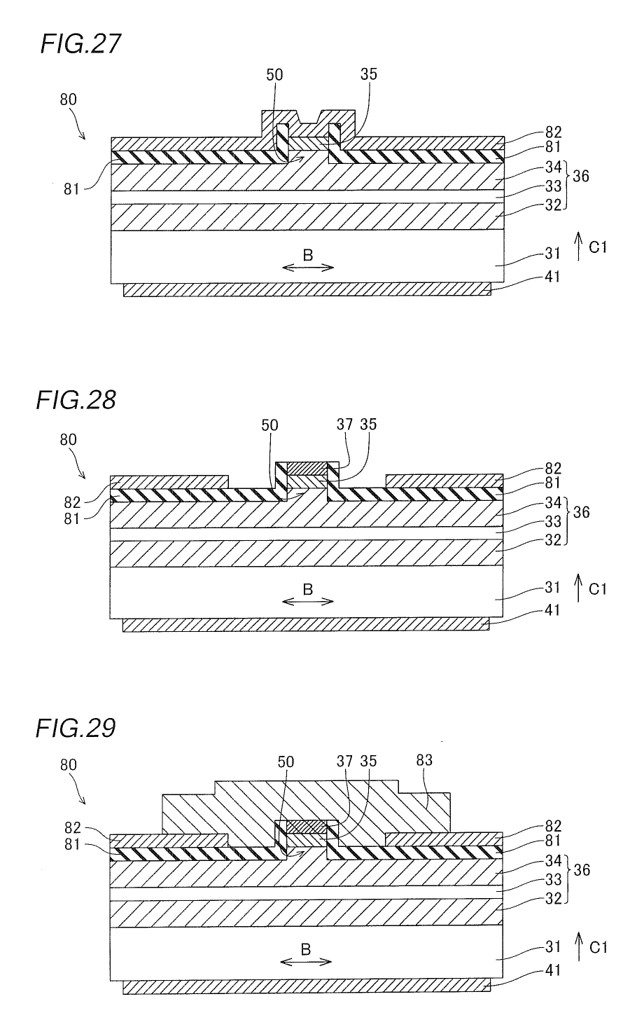

Referring to FIGS. 26 to 29, no p-side ohmic electrode 37 is formed on a ridge 50 on regions in the vicinity of cavity facets 80a in a semiconductor laser device 80 according to a fifth embodiment, dissimilarly to the aforementioned first embodiment. FIG. 27 shows a cross section taken along the line 5000-5000 in FIG. 26, and FIG. 28 shows a cross section taken along the line 5100-5100 in FIG. 26. FIG. 29 shows a cross section taken along the line 5200-5200 in FIG. 26.

According to the fifth embodiment, a current blocking layer 81 having a prescribed thickness is formed along a surface shape (convex shape) of a p-type cladding layer 34 in a direction B, as shown in FIGS. 27 to 29. Therefore, at a position shown in FIG. 27 (cross section taken along the line 5000-5000 in FIG. 26), a thermal conductive film 82 made of Si, having a thickness of about 300 nm is formed to protrude in a convex shape on a portion of the ridge 50. The thermal conductive film 82 is an example of the “radiation layer” in the present invention. At the position shown in FIG. 27, no p-side ohmic electrode 37 is formed, and hence the thermal conductive film 82 is formed to be in direct contact with a p-side contact layer 35 of the ridge 50.

According to the fifth embodiment, a p-side pad electrode 83 is formed along the shape of the ridge 50, as shown in FIG. 29. The p-side pad electrode 83 is in contact with the thermal conductive film 82 at a position (cross section taken along the line 5200-5200 in FIG. 26) shown in FIG. 29, while the p-side pad electrode 83 is not in contact with the thermal conductive film 82 at a position (cross section taken along the line 5100-500 in FIG. 26) shown in FIG. 28. In other words, the p-side ohmic electrode 37 is exposed outside from the ridge 50 at the position shown in FIG. 28. The p-side pad electrode 83 is an example of the “pad electrode” in the present invention.

As shown in FIGS. 26 and 27, the thermal conductive film 82 covers the regions in the vicinity of the cavity facets 80a (see FIG. 26) of the semiconductor laser device 80, and hence heat is excellently radiated from the ridge 50 similarly to the aforementioned first embodiment. The p-side pad electrode 83 is in contact with the thermal conductive film 82 at the position shown in FIG. 29, and hence heat diffused from the vicinity of the cavity facets 80a to the thermal conductive film 82 is also absorbed in addition to absorption of the heat of the ridge 50 on the device central region.

The remaining structure and manufacturing process of the semiconductor laser device 80 according to the fifth embodiment are similar to those of the aforementioned first embodiment.

According to the fifth embodiment, as hereinabove described, the semiconductor device layer 36 has regions formed with no p-side ohmic electrode 37 in the vicinity of the cavity facets 80a, whereby no current is supplied to the ridge 50 in the vicinity of the cavity facets 80a, and hence a leakage current on the cavity facets 80a can be reduced.

According to the fifth embodiment, the thermal conductive film 82 is formed on the regions formed with no p-side ohmic electrode 37 on the ridge 50 in the vicinity of the cavity facets 80a, whereby heat generated in the cavity facets 80a following light absorption can be effectively diffused to the p-side pad electrode 83 (see FIG. 29) through the thermal conductive film 82 (see FIG. 27). The remaining effects of the fifth embodiment are similar to those of the aforementioned first embodiment.

### Sixth Embodiment

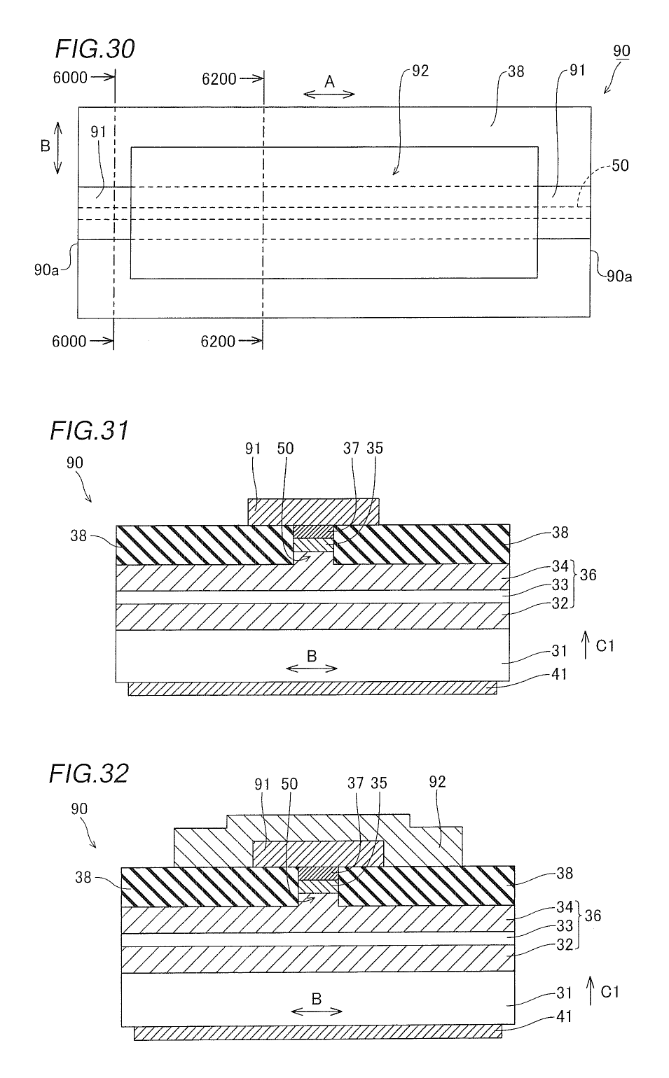

Referring to FIGS. 30 to 32, a thermal conductive film 91 made of ITO is formed on a ridge 50 in a semiconductor laser device 90 according to a sixth embodiment, dissimilarly to the aforementioned first embodiment. FIG. 31 shows a cross section taken along the line 6000-6000 in FIG. 30. FIG. 32 shows a cross section taken along the line 6200-6200 in FIG. 30.

According to the sixth embodiment, the thermal conductive film 91 made of ITO, having a thickness of about 100 nm is formed along an overall region in a direction A from a cavity facet 90a on a first side to a cavity facet 90a on a second side to cover an upper portion (broken line) of the ridge 50 and a prescribed region on an adjacent current blocking layer 38, as shown in FIG. 30. The ITO is widely employed as a transparent conductive film. The thermal conductive film 91 is an example of the “radiation layer” in the present invention. Therefore, the thermal conductive film 91 is formed to be in direct contact with and cover upper surfaces of a p-side ohmic electrode 37 (see FIG. 4) and the current blocking layer 38 (see FIG. 4) adjacent on both sides at a position (cross section taken along the line 6000-6000 in FIG. 30) shown in FIG. 31. A material (ITO) having thermal conductivity (about 8.2 W/m·K) larger than thermal conductivity of the current blocking layer 38 is employed for the thermal conductive film 91. Thus, heat of the ridge 50 on the regions in the vicinity of cavity facets 90a can be diffused toward a center of the semiconductor laser device 90 in a direction A through the thermal conductive film 91.

As shown in FIG. 30, a p-side pad electrode 92 is formed to cover a region except the prescribed region in the vicinity of the cavity facets 90a. The p-side pad electrode 92 is formed to be in direct contact with the prescribed region of the upper surface of the current blocking layer 38 at a position (cross section taken along the line 6200-6200 in FIG. 30) shown in FIG. 32 in addition to the thermal conductive film 91. Therefore, the p-side pad electrode 92 further absorbs heat of the ridge 50 absorbed by the thermal conductive film 91. The p-side pad electrode 92 is an example of the “pad electrode” in the present invention.

The remaining structure and the manufacturing process of the semiconductor laser device 90 according to the sixth embodiment are similar to those of the aforementioned first embodiment.

According to the sixth embodiment, as hereinabove described, the thermal conductive film 91 made of ITO is formed to be located in the vicinity of the cavity facets 90a of the semiconductor device layer 36 above the ridge 50, whereby heat particularly generated on the regions in the vicinity of the cavity facets 90a in heat generated from the ridge 50 extending in a cavity direction can be excellently radiated outside through the thermal conductive film 91 formed above the ridge 50 when operating the semiconductor laser device 90. In other words, also when no p-side pad electrode 92 made of metal is formed on the regions in the vicinity of the cavity facets 90a, the thermal conductive film 91 serves the function of facilitating heat radiation from the regions in the vicinity of the cavity facets 90a. Thus, thermal degradation due to temperature increase in the cavity facets 90a of the semiconductor laser device 90 can be suppressed, similarly to the aforementioned embodiment.

According to the sixth embodiment, the thermal conductive film 91 made of ITO is employed, whereby a current is effectively supplied to the p-side ohmic electrode 37 on the upper portion of the ridge 50 in the vicinity of the cavity facets 90a, not in contact with the p-side pad electrode 92 through the ITO film, with high electric conductivity, formed in contact with the p-side pad electrode 92, and hence a threshold current of the semiconductor laser device 90 can be reduced. The remaining effects of the sixth embodiment are similar to those of the aforementioned first embodiment.

### Seventh Embodiment

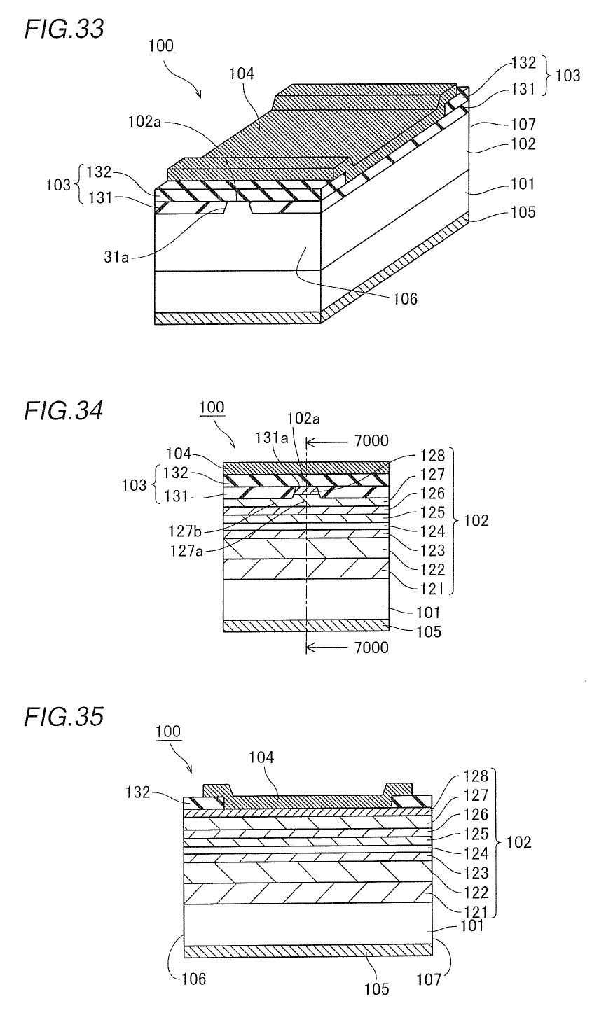

A structure of a semiconductor laser device 100 according to a seventh embodiment of the present invention will be now described with reference to FIGS. 33 to 35.

In the semiconductor laser device 100 according to the seventh embodiment of the present invention, a semiconductor multilayer portion 102 made of a plurality of nitride-based semiconductor layers, an insulating layer 103 and a p-side electrode 104 are successively formed on an upper surface ((0001) Ga plane) of a substrate 101 made of n-type GaN, and an n-side electrode 105 is formed on a lower surface ((000-1) N (nitrogen) plane) of the substrate 101, as shown in FIG. 33. The semiconductor multilayer portion 102 and the p-side electrode 104 are examples of the “semiconductor device layer” and the “pad electrode” in the present invention, respectively.

A ridge 102a protruding in the form of a stripe is formed on an upper surface of the semiconductor multilayer portion 102, and front and rear facets 106 and 107 of the semiconductor laser device 100 are formed substantially perpendicular to an extensional direction of the ridge 102a respectively. The ridge 102a is an example of the “projecting portion” or the “current path” in the present invention, and the front and rear facets 106 and 107 are examples of the “cavity facet” in the present invention. Facet protective films (not shown) are formed on the front and rear facets 106 and 107 respectively.

In the semiconductor multilayer portion 102, a buffer layer 121 made of n-type GaN having a thickness of about 1 μm, an n-type cladding layer 122 made of n-type Al_{0.15}Ga_{0.85}N having a thickness of about 1 μm, an n-side optical guide layer 123 made of n-type GaN having a thickness of about 0.1 μm, an MQW active layer 124, a cap layer 125 made of undoped Al_{0.3}Ga_{0.7}N having a thickness of about 20 nm, a p-side optical guide layer 126 made of p-type GaN having a thickness of about 0.1 μm, a p-type cladding layer 127 made of p-type Al_{0.15}Ga_{0.85}N and a p-side contact layer 128 made of undoped Ga_{0.95}In_{0.05}N having a thickness of about 10 nm are successively stacked from a side of the substrate 101, as shown in FIGS. 34 and 35.

The MQW active layer 124 has a structure in which four barrier layers of undoped Ga_{0.95}In_{0.05}N having a thickness of about 15 nm and three well layers of undoped Ga_{0.9}In_{0.1}N having a thickness of about 4 nm are alternately formed.

The p-type cladding layer 127 includes a projecting portion 127a having a width of about 1.5 μm and a thickness of about 0.5 μm formed in the form of a stripe on a substantially center of the upper surface and a planar portion 127b having a thickness of about 50 nm located on the both sides of the projecting portion 127a. The p-side contact layer 128 is formed only on the upper surface of the projecting portion 127a, and the projecting portion 127a of the p-type cladding layer 127 and the p-side contact layer 128 constitute the ridge 102a.

The insulating layer 103 is constituted by a first insulating layer 131 and a second insulating layer 132 formed on the semiconductor multilayer portion 102. The first insulating layer 131 is made of SiO₂ having a thickness of about 0.3 μm. The first insulating layer 131 is formed on side surfaces of the ridge 102a and an upper surface of the planar portion 127b of the p-type cladding layer 127, and has a striped opening 131a where the upper surface of the ridge 102a is exposed. The second insulating layer 132 is made of AlN with a thickness of about 0.5 μm, and is formed on first insulating layer 131 and the ridge 102a in the vicinity of the front and rear facets 106 and 107 (regions inward from the front and rear facets 106 and 107 by about 20 μm). Thermal conductivity (about 150 W/m·K) of AlN constituting the second insulating layer 132 is larger than thermal conductivity (about 1.4 W/m·K) of SiO₂ constituting the first insulating layer 131. The upper surface (p-side contact layer 128) of the ridge 102a is exposed in the opening 131a of the upper surface of the ridge 102a formed with no first insulating layer 131 and no second insulating layer 132. The first insulating layer 131 and the second insulating layer 132 are examples of the “current blocking layer” and the “radiation layer” in the present invention, respectively.

The p-side electrode 104 is formed on inside the opening 131a of the first insulating layer 131 and an peripheral portion thereof, a Pd layer having a thickness of about 1 μm, a Pt layer having a thickness of about 10 nm and an Au layer having a thickness of about 0.2 μm are successively stacked in this order. The p-side electrode 104 is electrically connected to the upper surface (p-side contact layer 128) of the ridge 102a exposed from the first insulating layer 131 and the second insulating layer 132 in the opening 131a. The p-side electrode 104 is formed to extend on the region stacked with the first insulating layer 131 and the second insulating layer 132 on the planar portion 127b of the p-type cladding layer 127. No p-side electrode 104 is formed on the insulating layer 103 on the regions in the vicinity of the front and rear facets 106 and 107 (striped regions inward from the front and rear facets 106 and 107 by about 15 μm), and the insulating layer 103 is exposed from the p-side electrode 104 in the vicinity of the front and rear facets 106 and 107.

The n-side electrode 105 is formed on the lower surface of the substrate 101, and a Ti layer having a thickness of about 5 nm, a Pt layer having a thickness of about 10 nm and an Au layer having a thickness of about 0.3 nm are successively stacked in this order. The n-side electrode 105 is electrically connected to the lower surface of the substrate 101. The semiconductor laser device 100 having a lasing wavelength of about 405 nm is formed in the aforementioned manner.

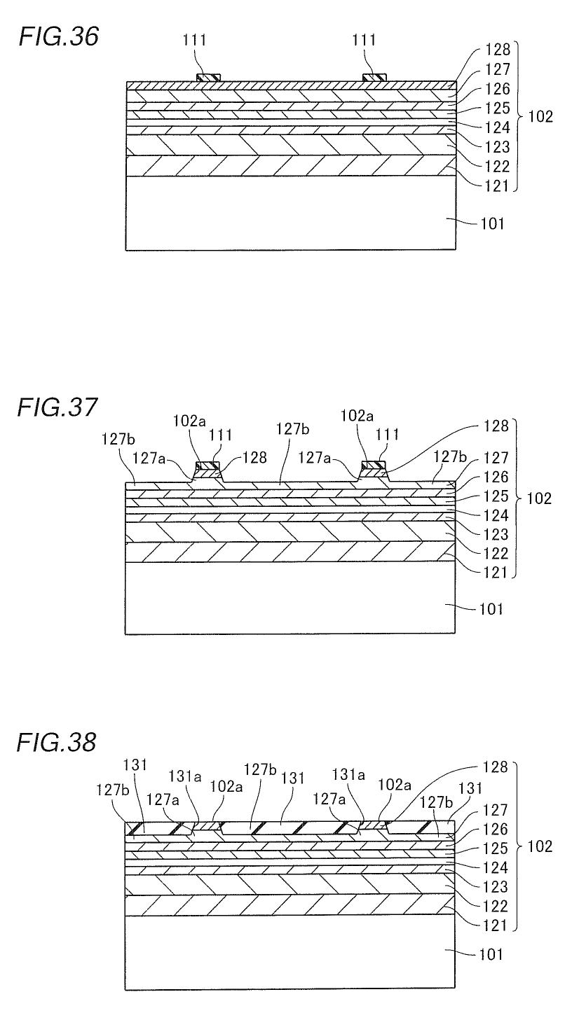

A manufacturing process for the semiconductor laser device 100 according to the seventh embodiment will be now described with reference to FIGS. 36 to 42.

As shown in FIG. 36, the semiconductor multilayer portion 102 is first formed on the upper surface ((0001) Ga plane) of the substrate 101 made of n-type GaN by MOCVD. The buffer layer 121 made of n-type GaN having a thickness of about 1 μm, the n-type cladding layer 122 made of n-type Al_{0.15}Ga_{0.85}N having a thickness of about 1 μm and the n-side optical guide layer 123 made of n-type GaN having a thickness of about 0.1 μm are successively grown in this order at a substrate temperature of about 1150° C.

The four barrier layers made of undoped Ga_{0.95}In_{0.05}N having a thickness of about 15 nm and the three well layers made of undoped Ga_{0.9}In_{0.1}N having a thickness of about 4 nm are alternately grown on the n-side optical guide layer 123 at a substrate temperature of about 850° C., thereby forming the MQW active layer 124. Then, the cap layer 125 made of undoped Al_{0.3}Ga_{0.7}N having a thickness of about 20 nm is grown on the MQW active layer 124.

The p-side optical guide layer 126 made of p-type GaN having a thickness of about 0.1 μm and the p-type cladding layer 127 made of p-type Al_{0.15}Ga_{0.85}N having a thickness of about 0.5 μm are successively grown in this order on the cap layer 125 at a substrate temperature of about 1150° C.

The p-side contact layer 128 made of undoped Ga_{0.95}In_{0.05}N having a thickness of about 10 nm is grown on the p-type cladding layer 127 at a substrate temperature of about 850° C. Thereafter, first masks 111 made of photoresist having a width of about 1.5 μm, extending in a direction perpendicular to plane of paper is formed on the p-side contact layer 128 at an interval of about 400 μm.

As shown in FIG. 37, the p-side contact layer 128 is removed on a region of an upper surface of a semiconductor multilayer portion 102a, formed with no first masks 111 by reactive ion etching (RIE), and a side of the upper surface of the p-type cladding layer 127 is removed by a depth of about 0.45 μm. Thus, the striped projecting portions 127a having a width of about 1.5 μm and the planar portions 127b having a thickness of about 50 nm are formed on the p-type cladding layer 127. The p-side contact layer 128 is formed only on the projecting portions 127a, and the ridges 102a including the projecting portions 127a protruding in the form of a stripe and the p-side contact layer 128 is formed on the upper surface of the semiconductor multilayer portion 102.

As shown in FIG. 38, the first insulating layer 131 made of SiO₂ having a thickness of about 0.3 μm is formed on the upper surfaces of the semiconductor multilayer portion 102 and the first masks 111 by electron cyclotron resonance chemical vapor deposition (ECRCVD) while not heating the substrate, and the first masks 111 are removed by etching with a solvent, thereby forming the striped openings 131a exposed from the first insulating layer 131 on the upper surfaces of the ridges 102a.

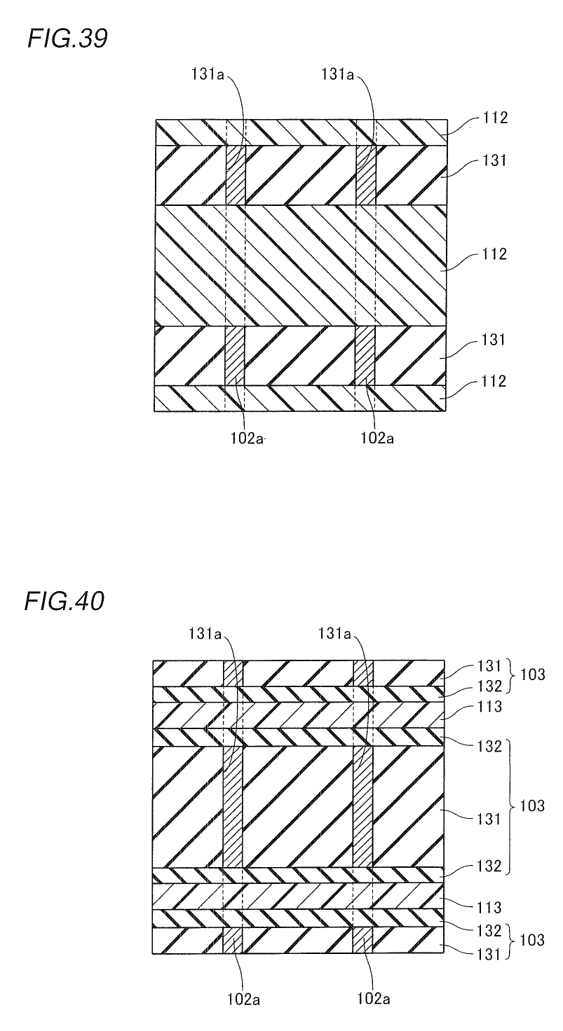

Second masks 112 made of photoresist extending in the form of a stripe in a direction substantially perpendicular to an extensional direction of the ridges 102a are formed on the first insulating layer 131 and the ridges 102a as shown in a top plan view in FIG. 39. The second masks 112 having a width of about 40 μm in the extensional direction of the ridges 102a are formed at an interval of about 800 μm.

Then, the second insulating layer 132 made of AlN having a thickness of about 0.3 μm is formed on the upper surfaces of the second masks 112 and the upper surfaces of the first insulating layer 131 and the ridges 102a exposed from the second masks 112 by ECR sputtering while not heating the substrate, and the second masks 112 are thereafter removed by etching with a solvent. Thus, the upper surfaces of the first insulating layer 131 and the ridges 102a are exposed on the striped regions formed with the second masks 112 as shown in a top plan view in FIG. 40.

Third masks 113 made of photoresist, having a width of about 30 μm and extending in the form of a stripe in a direction substantially perpendicular to the extensional direction of the ridges 102a are formed on a substantial center of the upper surface of the second insulating layer 132 formed to extend in a direction substantially perpendicular to the extensional direction of the ridges 102a.

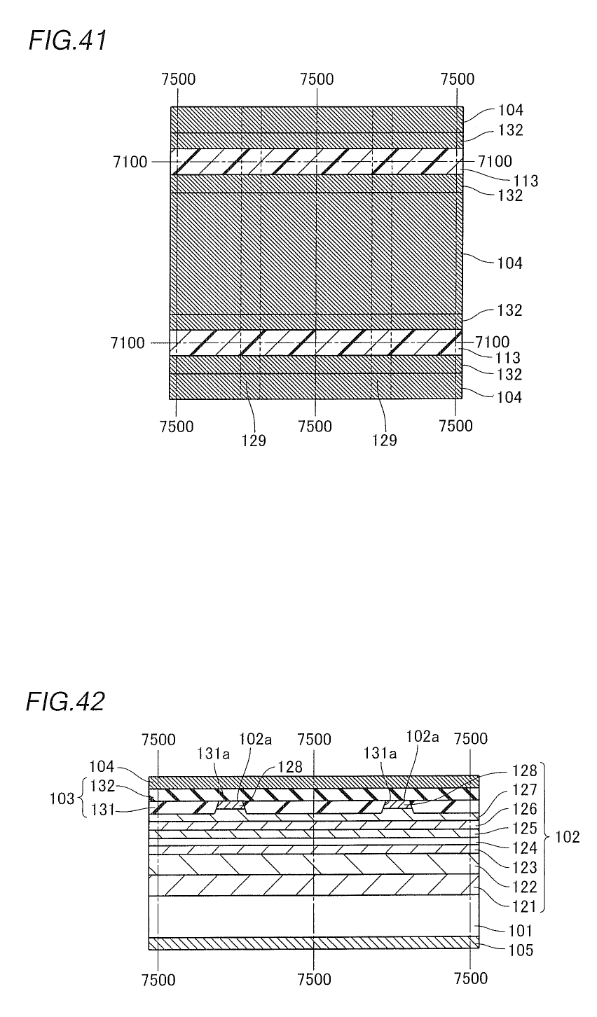

As shown in a top plan view in FIG. 41, a Pd layer having a thickness of about 1 nm, the Pt layer having a thickness of about 10 nm, the Au layer having a thickness of about 0.2 m constituting the p-side electrode 104 are successively stacked in this order on the third masks 113, the insulating layer 103 and the ridges 102a in the openings 131a by electron-beam (EB) deposition, and the third masks 113 are thereafter removed by etching with a solvent. Thus, the upper surface of the second insulating layer 132 is exposed from the p-side electrode 104 on the striped regions formed with the third masks 113.

As shown in FIG. 42, the thickness of the substrate 101 is reduced to about 100 μm by polishing and etching a side of the lower surface of the substrate 101, and the Ti layer having a thickness of about 5 nm, the Pt layer having a thickness of 10 nm and the Au layer having a thickness of about 0.3 μm constituting the n-side electrode 105 are thereafter stacked on the lower surface of the substrate 101 in this order by EB deposition.

Finally, respective devices are separated by cleaving on the substantial center (line 7100-7100 in FIG. 41) of the second insulating layer 132 exposed in the form of a stripe from the p-side electrode 104 and breaking on the substantial center between the respective ridges 102a (line 7500-7500 in FIGS. 41 and 42). The semiconductor laser device 100 according to the seventh embodiment shown in FIG. 33 is manufactured in the aforementioned manner.

According to the seventh embodiment, as hereinabove described, the second insulating layer 132 having larger thermal conductivity than the first insulating layer 131 is formed on the ridge 102a of the semiconductor multilayer portion 102, and hence heat generated in the vicinity of the front and rear facets 106 and 107 employed as the cavity facets is easily radiated in a direction of the upper direction of the semiconductor laser device 100 as compared with a case where an insulating layer made of the same material as the first insulating layer 131 is formed on the ridge 102a. Thus, increase in a temperature in the vicinity of the cavity facets can be suppressed, and hence facet breakage due to a COD phenomenon is unlikely to occur.

In the vicinity of the ridge 102a, the first insulating layer 131 is formed for performing light confinement, and it is preferentially required to effectively ensure difference in an refractive index between the ridge 102a and the first insulating layer 131. Therefore, it was difficult to improve heat radiation capacity to the upper surface of the device. In this semiconductor laser device 100, however, the degree of freedom in device design is improved by forming the second insulating layer 132a made of a material different from that of the first insulating layer 131 and light confinement characteristics and heat radiation capacity can be improved.

In this semiconductor laser device 100, the product of the thickness of the first insulating layer 131 (about 0.3 μm) and the refractive index (SiO₂: about 1.46) are larger than ½ of the lasing wavelength (about 405 nm). According to this structure, light can be easily inhibited from leaking to the second insulating layer 132 and stable light confinement can be performed.

In this semiconductor laser device 100, the first insulating layer 131 is made of SiO₂ having smaller refractive index than the second insulating layer 132 made of AlN (refractive index: about 2.3), and hence light from the MQW active layer 124 can be inhibited from easily leaking to a portion above the current path formed with the second insulating layer 132, and hence staple light confinement can be easily performed.

According to the seventh embodiment, the second insulating layer 132 formed on the ridge 102a in the vicinity of the front and rear facets 106 and 107 is formed to extend on the first insulating layer 131. Thus, defects such as separation of the second insulating layer 132 from the ridge 102a in a cleavage step of forming the front and rear facets 106 and 107 can be suppressed.

According to the seventh embodiment, the p-side electrode 104 is formed on the region other than the vicinity of the front and rear facets 106 and 107 of the upper surface of the insulating layer 103. Thus, the p-side electrode 104 containing metal which has higher viscosity than semiconductor and is unlikely to be cleaved is not required to be separated in the aforementioned cleavage step. Consequently, defects such as cleavage failure of the substrate 101 and the semiconductor multilayer portion 102 or separation of the p-side electrode 104 from the insulating layer 103 can be suppressed.

According to the seventh embodiment, the substrate 101 and the semiconductor multilayer portion 102 are made of nitride-based semiconductor. The nitride-based semiconductor has larger thermal conductivity than other semiconductor materials, and hence heat can be effectively radiated to a side of a base even when the side of the n-side electrode 105 is mounted on the base or the like. The remaining effects of the seventh embodiment are similar to those of the aforementioned first embodiment.

### Modification of Seventh Embodiment

A structure of a semiconductor laser device 200 according to a modification of the seventh embodiment of the present invention will be described with reference to FIGS. 36, 46 and 44. In the semiconductor layer device 200, a structure substantially similar to that of the semiconductor laser device 100 according to the aforementioned seventh embodiment is denoted by the same reference numerals and redundant description is omitted except the following points.

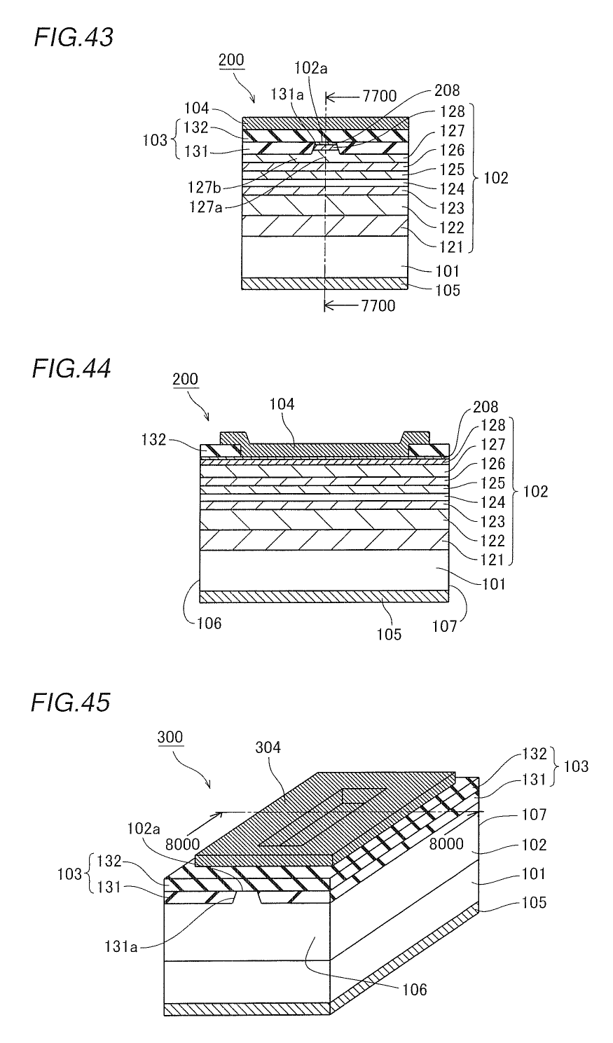

In the semiconductor laser device 200 according to the modification of the seventh embodiment of the present invention, a conductive layer 208 formed by successively stacking a Pd layer having a thickness of about 1 nm and a Pt layer having a thickness of 30 nm is formed on an upper surface of a p-side contact layer 128 constituting a ridge 102a, as shown in FIGS. 43 and 44. The conductive layer 208 is an example of the “metal electrode layer” in the present invention.

In a manufacturing process for the semiconductor laser device 200, the p-side contact layer 128 is formed on a p-type cladding layer 127 and the conductive layer 208 is formed by EB deposition. Then, first masks 111 (see FIG. 36) are formed on a surface of the conductive layer 208, and a side of the upper surface of the conductive layer 208, the p-side contact layer 128 and the p-type cladding layer 127 are removed on regions of the upper surface of the semiconductor multilayer portion 102, formed with no the first masks 111 by a thickness of about 0.45 μm, by RIE. The remaining manufacturing process is similar to the manufacturing process of the semiconductor laser device 100 according to the aforementioned seventh embodiment.

According to the modification of the seventh embodiment, as hereinabove described, the conductive layer 208 made of a Pd/Pt multilayer film is formed between the ridge 102a (p-side contact layer 128) and the second insulating layer 132 as well as between the ridge 102a and the p-side electrode 104, whereby heat radiation capacity with respect to an extensional direction of the ridge 102a can be improved, and uniformity of an injected current with respect to the extensional direction of the ridge 102a can be improved. This conductive layer 208 is covered with the second insulating layer 132 in the vicinity of front and rear facets 106 and 107, and hence defects such as separation of the conductive layer 208 from the ridge 102a can be suppressed in the aforementioned cleavage step.

According to the modification of the seventh embodiment, Pd is employed as the conductive layer 208 on a side in contact with the p-side contact layer 128, and hence ohmic contact between the conductive layer 208 and the p-side contact layer 128 can be excellently performed. The remaining effects of the modification of the seventh embodiment are similar to those of the aforementioned seventh embodiment.

### Eighth Embodiment

A semiconductor laser device 300 according to an eighth embodiment of the present invention will be described with reference to FIGS. 36 to 38, FIG. 42 and FIGS. 45 to 49. In the semiconductor layer device 300, the structure substantially similar to that of the semiconductor laser device 200 according to the aforementioned modification of the seventh embodiment is denoted by the same reference numerals and redundant description is omitted except the following points.

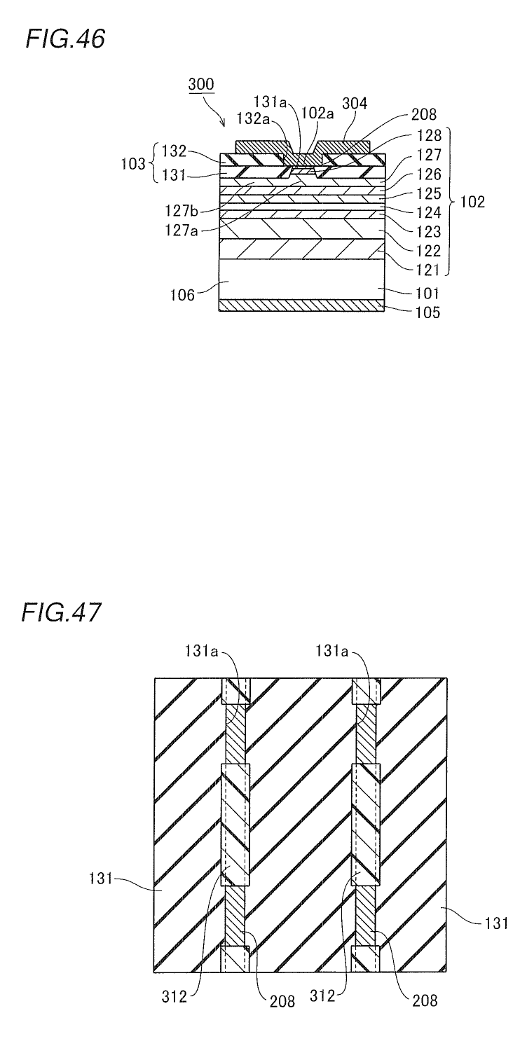

In the semiconductor laser device 300 according to the eighth embodiment of the present invention, a second insulating layer 132 is formed not only in the vicinity of front and rear facets 106 and 107 but also on a substantially overall upper surface of a first insulating layer 131 and a ridge 102a in the vicinity of the front and rear facets 106 and 107, as shown in FIGS. 45 and 46. In the second insulating layer 132, an opening 132a with a length of about 760 μm in an extensional direction of the ridge 102a and a width of about 10 μm in a direction substantially perpendicular to the extensional direction of the ridge 102a is formed on the ridge 102a, and the upper surface of the first insulating layer 131 and an upper surface of the conductive layer 208 on the ridge 102a exposed from an opening 131a formed on the first insulating layer are exposed in the opening 132a.

A p-side electrode 304 is formed on inside the opening 132a of the second insulating layer 132 and an peripheral portion thereof, and is electrically connected to the conductive layer 208 in the opening 131a. No p-side electrode 304 is formed on an insulating layer 103 on the regions (striped regions inward from both side surfaces by about 15 μm) in the vicinity of the side surfaces of the semiconductor laser device 300, and the insulating layer 103 (second insulating layer 132) is exposed from the p-side electrode 304 in the vicinity of the side surfaces. The p-side electrode 304 is an example of the “pad electrode” in the present invention.

The manufacturing process for the semiconductor laser device 300 according to the eighth embodiment is similar to the manufacturing process for the semiconductor laser device 200 except the following points.

In other words, the first insulating layer 131 having the striped opening 131a is so formed that the upper surface of the conductive layer 208 formed on the ridge 102a of the upper surface of the semiconductor multilayer portion 102 is exposed in the manufacturing process for the semiconductor laser device 300 with reference to FIGS. 36 to 38 and the aforementioned manufacturing process of the semiconductor laser device 200. Thereafter, a second masks 312 made of photoresist are formed on the conductive layer 208 and the first insulating layer 131, as shown in FIG. 47. The second masks 312 have a length of about 760 μm in an extensional direction of the conductive layer 208 and a width of about 10 μm in a direction substantially perpendicular to the extensional direction of the conductive layer 208, and are formed at an interval about 800 μm with respect to the extensional direction of the conductive layer 208.

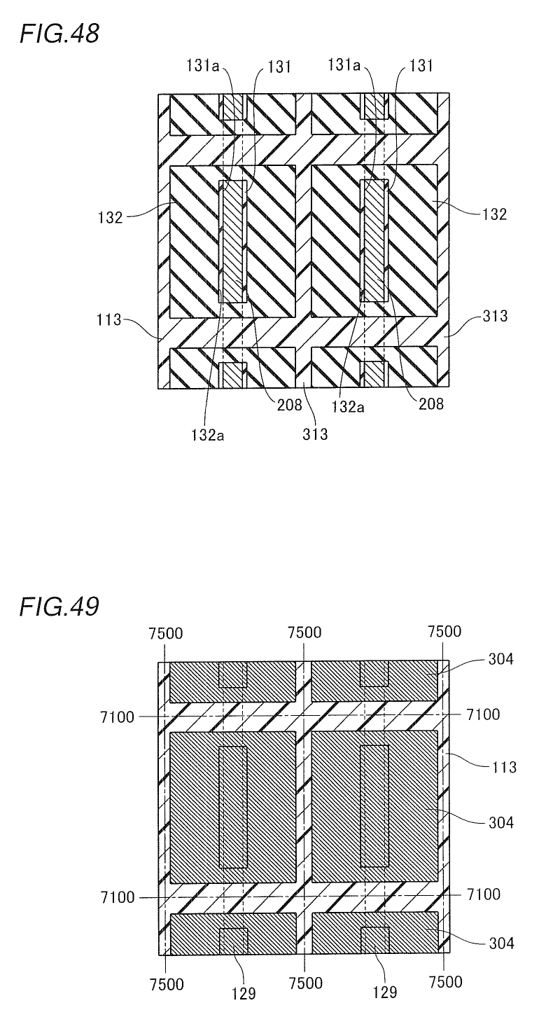

Then, the second insulating layer 132 made of AlN having a thickness of about 0.3 μm is formed on the upper surfaces of the second masks 312 and the upper surfaces of the first insulating layer 131 and the conductive layer 208 exposed from the second masks 312 by ECR sputtering while not heating the substrate, and the second masks 312 are thereafter removed by etching with a solvent. Thus, the striped openings 132a are formed on regions formed with the second masks 312, and the upper surface of the first insulating layer 131 and the upper surface of the conductive layer 208 on the ridges 102a exposed from the openings 131a formed on the first insulating layer are exposed in the openings 132a as shown in a top plan view in FIG. 48.

A third mask 313 made of photoresist is formed in the form of a lattice on the upper surface of the second insulating layer 132 to enclose the respective openings 132a. The third mask 313 has a width of about 30 μm in the direction substantially perpendicular to the extensional direction of the conductive layer 208 on a substantial center of the respective openings 132a vertically adjacent to each other and a width of about 30 μm in the extensional direction of the conductive layer 208 on a substantial center of the respective openings 132a laterally adjacent to each other.

As shown in a top plan view in FIG. 49, the p-side electrodes 304 are formed on the third mask 313, the second insulating layer 132, the conductive layer 208 in the opening 132a and the first insulating layer 131 by EB deposition, and the third mask 313 is thereafter removed by etching with a solvent. Thus, the upper surface of the second insulating layer 132 is exposed from the p-side electrode 304 on the latticed region formed with the third mask 313.

Referring to FIG. 42, respective devices are separated by polishing and etching a side of a lower surface of the substrate 101, forming the n-side electrode 105 on the lower surface of the substrate 101, cleaving on the substantial center (line 7100-7100 in FIG. 49) of the region extending in the direction perpendicular to the extensional direction of the conductive layer 208 in the second insulating layer 132 exposed in the form of a lattice from the p-side electrode 304, and breaking on the substantial center (line 7500-7500 in FIG. 49) between the second insulating layer 132 exposed to extending in the extensional direction of the conductive layers 208 on the substantial center between the respective conductive layers 208. The semiconductor laser device 300 according to the eighth embodiment shown in FIG. 47 is manufactured in the aforementioned manner.

According to the eighth embodiment, as hereinabove described, the first insulating layer 131 and the second insulating layer 132 are stacked on the planar portion 127b of the region other than the ridge 102a on the upper surface of the semiconductor multilayer portion 102. The p-side electrode 304 formed on the conductive layer 208 on the ridge 102a is formed to extend from the inside of the opening 132a to the region where the first insulating layer 131 and the second insulating layer 132 are stacked. Thus, a distance between the p-side electrode 304 and the semiconductor multilayer portion 102 can be easily separated from each other on the planar portion 127b, and hence the parasitic capacitance (electrostatic capacitance) between the p-side electrode 304 and the semiconductor multilayer portion 102 can be reduced. Consequently, high frequency operating characteristics of the semiconductor laser device 300 can be improved.

According to the eighth embodiment, wire bonding can be performed at a position separated from the ridge 102a when wire bonding is performed on the p-side electrode 304 formed to extend on the region where the first insulating layer 131 and the second insulating layer 132 are stacked, and hence damage to the ridge 102a can be reduced. In the aforementioned bonding, the first insulating layer 131 and the second insulating layer 132 are stacked, and hence damage to the semiconductor multilayer portion 102 can be reduced. Thus, yield in wire bonding is improved and reliability is improved.

According to the eighth embodiment, the p-side electrode 304 is formed on the region, other than the vicinity of the side surfaces of the device, of the upper surface of the insulating layer 103, whereby the p-side electrode 304 containing metal which has higher viscosity than semiconductor and is unlikely to be cleaved is not required to be separated in the aforementioned cleavage step. Consequently, defects such as separate failure of the substrate 101 and the semiconductor multilayer portion 102 or separation of the p-side electrode 304 from the insulating layer 103 can be suppressed.

According to the eighth embodiment, the upper surface of the p-side electrode 304 is flattened, and hence when the p-side pad electrode 304 is bonded to a base such as a heat sink in a junction-down system, the semiconductor laser device 300 can be stably bonded to the base. The remaining effects of the semiconductor laser device 300 according to the eighth embodiment are similar to those of the aforementioned modification (semiconductor laser device 200) of the seventh embodiment.

### Modification of Eighth Embodiment

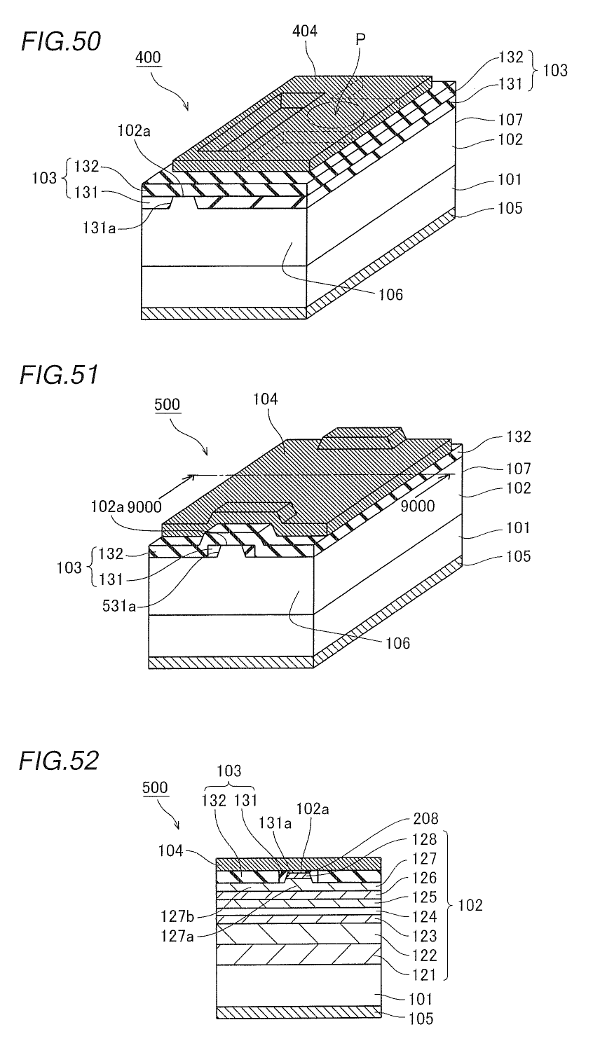

Referring to FIG. 50, a semiconductor laser device 400 according to a modification of the eighth embodiment has a structure substantially similar to that of the semiconductor laser device 300 according to the aforementioned eighth embodiment except that a ridge 102a formed on an upper surface of a semiconductor multilayer portion 102 is formed on a position closer to a left side surface from a center of an upper surface, and the structure substantially similar to that of the semiconductor laser device 300 according to the aforementioned eighth embodiment is denoted by the same reference numerals and redundant description is omitted.

In the semiconductor laser device 400 according to the modification of the eighth embodiment of the present invention, the ridge 102a is formed on the position closer to the side surface from the center of the upper surface, and hence a planar region can be more widely secured on an upper surface of the p-side electrode 404, and hence wire bonding can be easily performed. The p-side electrode 404 is formed to a shape (see broken lines in FIG. 50) extending only in the vicinity of a region (portion P in FIG. 50, for example) required for bonding, whereby an area of a region where the p-side electrode 404 and the semiconductor multilayer portion 102 are opposed to each other can be reduced, and hence parasitic capacitance (electrostatic capacitance) between the p-side electrode 404 and the semiconductor multilayer portion 102 can be further reduced. The p-side electrode 404 is an example of the “pad electrode” in the present invention.

The remaining effects of the semiconductor laser device 400 according to the modification of the eighth embodiment are similar to those of the aforementioned eighth embodiment.

### Ninth Embodiment

Referring to FIGS. 51 and 52, in a semiconductor laser device 500 according to a ninth embodiment, a structure substantially similar to that of the semiconductor laser device 200 according to the aforementioned modification of the seventh embodiment is denoted by the same reference numerals and redundant description is omitted except the following points.

In the semiconductor laser device 500 according to the ninth embodiment of the present invention, the first insulating layer 131 is formed only in the vicinity of a ridge 102a as shown in FIGS. 51 and 52. In other words, the first insulating layer 131 is formed on side surfaces of the ridge 102a and a region, having a width of about 10 μm from each side surface of the ridge 102a, on an upper surface of the planar portion 127b of the p-type cladding layer 127. The second insulating layer 132 is formed on an upper surface of the planar portion 127b formed with no first insulating layer 131 and the ridge 102a in the vicinity of the front and rear facets 106 and 107 through the conductive layer 208.

According to the ninth embodiment, as hereinabove described, the first insulating layer 131 having small thermal conductivity is formed only in the vicinity of the ridge 102a, and the second insulating layer 132 having large thermal conductivity is formed to extend on the upper surface of the planar portion 127b formed with no first insulating layer 131 other than the vicinity of the ridge 102a. Thus, heat radiation capacity from the upper surface of the semiconductor multilayer portion 102 can be further improved. Consequently, increase in a temperature of the overall device can be suppressed and hence reliability can be further improved. The remaining effects of the semiconductor laser device 500 according to the ninth embodiment are similar to those of the aforementioned modification of the seventh embodiment.

### Tenth Embodiment

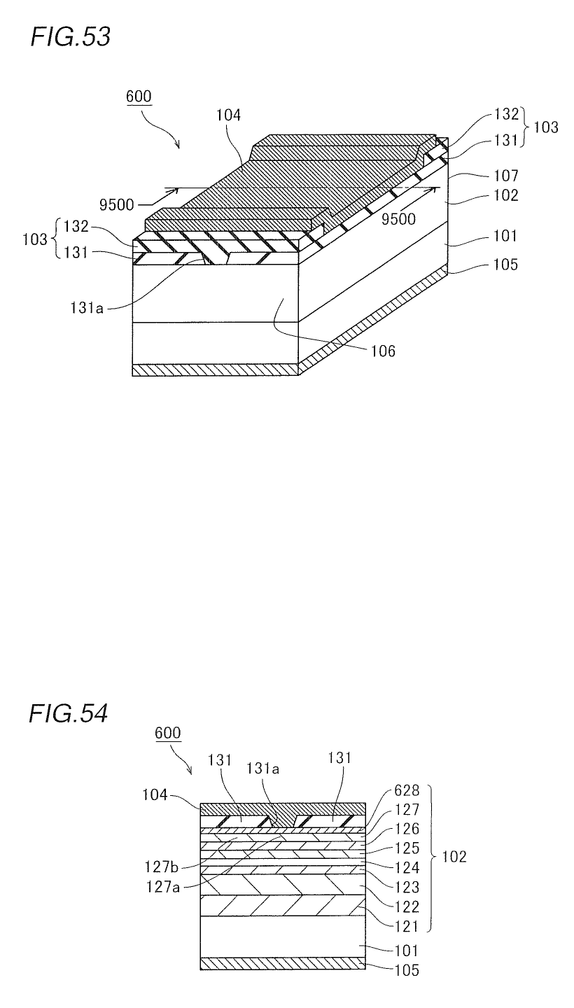

Referring to FIGS. 53 and 54, in a semiconductor laser device 600 according to a tenth embodiment, a structure substantially similar to that of the semiconductor laser device 100 according to the aforementioned seventh embodiment is denoted by the same reference numerals and redundant description is omitted except the following points.

In the semiconductor laser device 600 according to the tenth embodiment of the present invention, no projecting portion is formed on an upper surface of a p-type cladding layer 127 formed on a side of an upper surface of a semiconductor multilayer portion 102, and a p-side contact layer 628 is formed on an overall upper surface of the p-type cladding layer 127, as shown in FIGS. 53 and 54. In other words, no ridge is formed in this semiconductor laser device 600, and a region directly under a striped opening 131a formed in the first insulating layer 131 serves as an optical waveguide region.

While this semiconductor laser device 600 is not a ridge waveguide semiconductor laser device shown in each of the aforementioned embodiments, the second insulating layer 132 having larger thermal conductivity than the first insulating layer 131 is formed on the semiconductor multilayer portion 102 in the opening 131a of the first insulating layer 131 in the vicinity of the front and rear facets 106 and 107 employed as cavity facet, and hence heat generated in the cavity facet is likely to be radiated in a direction of an upper surface of the semiconductor laser device 600 as compared with a case where an insulating layer made of the same material as the first insulating layer 131 is formed on the semiconductor multilayer portion 102 in the opening 131a. Thus, increase in a temperature in the vicinity of the cavity facets can be suppressed, and hence similar effects that facet breakage due to a COD phenomenon is unlikely to occur exert.

The remaining effects of the semiconductor laser device 600 according to the tenth embodiment is similar to those of the aforementioned seventh embodiment.

### Eleventh Embodiment

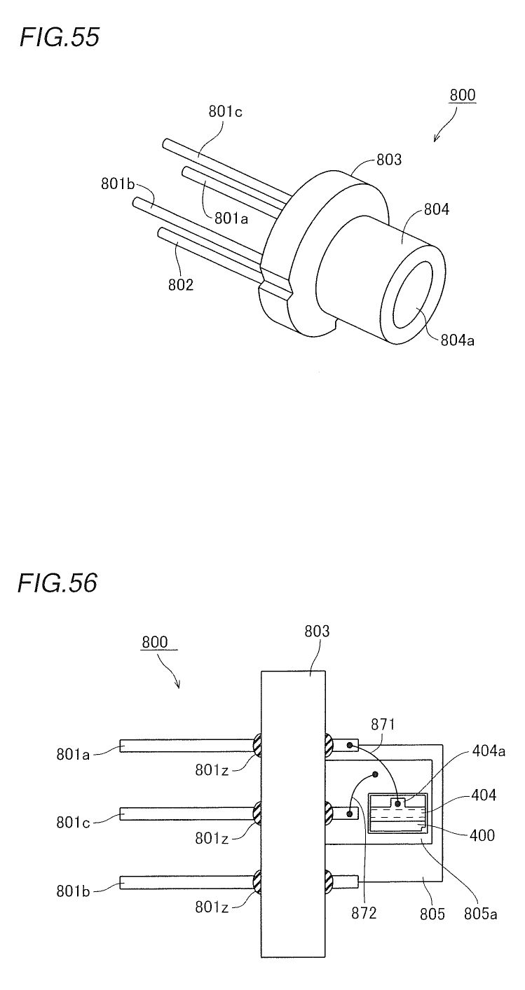

An optical pickup 900 comprising a laser apparatus 800 according to an eleventh embodiment of the present invention will be described with reference to FIG. 50 and FIGS. 55 to 57.

The laser apparatus 800 according to the eleventh embodiment of the present invention is made of a conductive material, and comprises a substantially rounded can package body 803, power feeding pins 801a, 801b, 801c and 802, and a lid body 804. The can package body 803 is provided with the semiconductor laser device 400 according to the aforementioned modification of the eighth embodiment, and is sealed by the lid body 804. The lid body 804 is provided with an extraction window 804a made of a material transmitting a laser beam. The power feeding pin 802 is mechanically and electrically connected to the can package body 803. The power feeding pin 802 is employed as an earth terminal. First ends of the power feeding pins 801a, 801b, 801c and 802, extending outside of the can package body 803 are connected to a operating circuit (not shown).

A conductive submount 805a is provided on a conductive support member 805 integrated with the can package body 803. The support member 805 and the submount 805a are made of excellent conductive and thermal conductive materials. The semiconductor laser device 400 is so bonded that an emission direction X of a laser is directed outside (to a side of the extraction window 804a) of the laser apparatus 800 and an emission point (waveguide formed below a ridge 102a) of the semiconductor laser device 400 is located on a centerline of the laser apparatus 800.

The power feeding pins 801a, 801b and 801c are electrically insulated from the can package body 803 by the insulating rings 801z, respectively. The power feeding pin 801a is connected to an upper surface of a wire bonding portion 404a of a p-side electrode 404 (see broken lines in FIG. 50) of the semiconductor laser device 400 through a wire 871. The power feeding pin 801c is connected to an upper surface of the submount 805a through a wire 872.

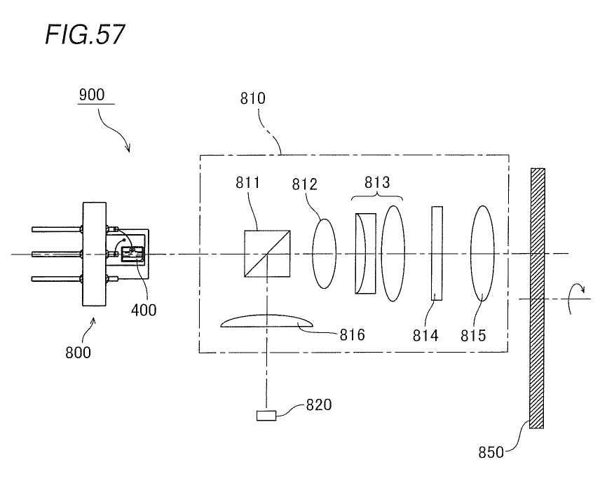

As shown in FIG. 57, the optical pickup 900 comprises an optical system 810 having the laser apparatus 800 mounted with the semiconductor laser device 400, a polarizing beam splitter (polarizing BS) 811, a collimator lens 812, a beam expander 813, a λ/4 plate 814, an objective lens 815 and a cylindrical lens 816, and a light detection portion 820.

In the optical system 810, the polarizing BS 811 totally transmits a laser beam emitted from the semiconductor laser device 400 and totally reflects the laser beam returned from an optical disc 850. The collimator lens 812 converts the laser beam from the semiconductor laser device 400 transmitting through the polarizing BS 811 to parallel light. The beam expander 813 includes a concave lens, a convex lens and an actuator (not shown). The actuator changes a distance of the concave lens and the convex lens in response to a servo signal from the servo circuit (not shown). Thus, a state of wavefront of the laser beam emitted from the semiconductor laser device 400 is amended.

The λ/4 plate 814 converts a linearly-polarized laser beam converted to substantially parallel light by the collimator lens 812 to circularly-polarized light. The λ/4 plate 814 converts the circularly-polarized laser beam returned from the optical disc 850 to linearly-polarized light. A direction of polarization of linearly-polarized light in this case is perpendicular to a direction of linear polarization of the laser beam emitted from the semiconductor laser device 400. Thus, the laser beam returned from the optical disc 850 is totally reflected by the polarizing BS 811. The objective lens 815 converges the laser beam transmitted through the λ/4 plate 814 on a surface (recording layer) of the optical disc 850. The objective lens 815 is movable in a focus direction, a tracking direction and a tilt direction in response to a servo signal (a tracking servo signal, a focus servo signal and a tilt servo signal) from the servo circuit by an objective lens actuator (not shown).

The cylindrical lens 816 and the light detection portion 820 are arranged along an optical axis of the laser beam totally reflected by the polarizing BS 811. The cylindrical lens 816 gives astigmatic action to an incident laser beam. The light detection portion 820 outputs a reproduced signal on the basis of intensity distribution of a received laser beam. The light detection portion 820 has a prescribed patterned detection region to obtain the reproduced signal as well as a focus error signal, a tracking error signal and a tilt error signal. The actuator of the beam expander 813 and the objective lens actuator are feedback-controlled by the focus error signal, the tracking error signal and the tilt error signal. Thus, the optical pickup 900 according to the eleventh embodiment of the present invention is formed.

According to the eleventh embodiment, as hereinabove described, the semiconductor laser device 400 according to the aforementioned modification of the eighth embodiment is employed in the optical pickup 900, and hence wire bonding to the wire bonding portion 404a through the wire 871 can be easily performed. An area of a region where the p-side electrode 404 and the semiconductor multilayer portion 102 are opposed to each other on the wire bonding portion 404a is reduced, and hence parasitic capacitance (electrostatic capacitance) between the p-side electrode 404 and the semiconductor multilayer portion 102 can be further reduced.

Although the present invention has been described and illustrated in detail, it is clearly understood that the same is by way of illustration and example only and is not to be taken by way of limitation, the spirit and scope of the present invention being limited only by the terms of the appended claims.

For example, while each of the aforementioned first to tenth embodiments is applied to the nitride-based semiconductor laser in which the semiconductor device layer is stacked on the n-type GaN substrate, the present invention is not restricted to this but may alternatively be applied to other semiconductor laser such as a GaAs-based semiconductor laser, an InP-based semiconductor laser and a ZnSeS-based semiconductor laser employed in an infrared semiconductor laser or a red semiconductor laser.

While the regions formed with no heat-radiation layer are formed on the lower portion of the pad electrode and the peripheral region thereof in the aforementioned first to fifth embodiments, the present invention is not restricted to this but the heat-radiation layer may be formed to exist on a prescribed region of the upper portion (upper surface) of the pad electrode in addition to the lower portion of the pad electrode and the peripheral region thereof. Also according to the structure of this modification, heat generated on the regions in the vicinity of the cavity facets can be effectively radiated outside through the heat-radiation layer and the pad electrode, and hence thermal degradation due to heat generated in the cavity facets can be suppressed.

While the transparent conductive film made of ITO is employed as the thermal conductive film 91 in the aforementioned sixth embodiment, the present invention is not restricted to this but other transparent conductive film made of ZnO doped with Al or Ga or SnO₂ doped with Sb or F (fluorine) may be employed. The aforementioned transparent conductive film has electrical resistivity of about 1×10⁻² Ωcm to about 1×10⁻⁴ Ωcm.

While SiO₂ is employed for the first insulating layer 131 and AlN is employed for the second insulating layer 132 in each of the aforementioned seventh to tenth embodiment, the present invention is not restricted to this but Al₂O₃ (thermal conductivity: about 32 W/m·K, refractive index: about 1.7), SiN (thermal conductivity: about 70 W/m·K, refractive index: about 2.0) or ZrO₂ (thermal conductivity: about 2 W/m·K, refractive index: about 2.2) can be employed as the first insulating layer 131. A material having larger thermal conductivity than the first insulating layer 131 can be employed as the second insulating layer 132. For example, SiN, Al₂O₃, diamond-like carbon (DLC) or the like can be employed for the second insulating layer 132 in addition to AlN, when the first insulating layer 131 is made of SiO₂.

In order to easily perform stable light confinement, the refractive index of the first insulating layer is preferably smaller than the refractive index of the second insulating layer, and hence SiN, AlN, Al₂O₃ or DLC is preferably employed as the second insulating layer, for example, when the first insulating layer is made of SiO₂. AlN, DLC or the like is preferably employed as the second insulating layer, when the first insulating layer is preferably made of Al₂O₃. AlN, DLC or the like is preferably employed as the second insulating layer, when the first insulating layer is preferably made of ZrO₂. In the aforementioned case, the first insulating layer and the second insulating layer are binary compounds containing the same element of the first insulating layer and the second insulating layer, the first insulating layer is made of oxide, the second insulating layer is made of nitride, so that the refractive index of the first insulating layer can easily rendered smaller than the refractive index of the second insulating layer, and adhesiveness between the first insulating layer and the second insulating layer can be improved.

While Pd/Pt multilayer film is employed for the conductive layer 208 in the aforementioned modification of the seventh embodiment, the present invention is not restricted to this but a metal material such as Pd, Ni, Al, Mo, Au, Ti, or a conductive material containing metal such as ITO can be employed, and an alloy layer and a multilayer made of these materials can be also employed. When the conductive layer is formed by the multilayer film, Pd, Ni or the like having excellent ohmic contact is preferably employed on the side of the semiconductor multilayer portion, while Pt, Mo or the like having excellent heat resistance is preferably employed on the side of the p-side electrode.

While a nitride-based semiconductor is employed for the substrate 101 and the semiconductor multilayer portion 102 in each of the aforementioned seventh to tenth embodiments, the present invention is not restricted to this but other semiconductor material can be employed. For example, GaN, GaAs, SiC or the like can be employed as the substrate 101. A phosphide-based semiconductor represented by AlInGaP or an arsenide-based semiconductor represented by AlInGaAs can be employed for the semiconductor multilayer portion 102. When the substrate 101 is made of GaAs, the phosphide-based semiconductor or the arsenide-based semiconductor is preferably employed as the semiconductor multilayer portion 102.

What is claimed is:

1. A semiconductor laser device comprising:
a semiconductor device layer having an emission layer and formed with a current path on a semiconductor layer in the vicinity of said emission layer;
a current blocking layer formed in the vicinity of said current path; and
a heat-radiation layer formed to be provided at least in the vicinity of a region formed with a cavity facet of said semiconductor device layer and be located above said current path, and having thermal conductivity larger than that of said current blocking layer.

2. The semiconductor laser device according to claim 1, further comprising a pad electrode formed on a region other than the vicinity of the region formed with said cavity facet of said semiconductor device layer, wherein
said heat-radiation layer is formed to be located above said current path of at least a region not formed with said pad electrode.

3. The semiconductor laser device according to claim 2, wherein
said heat-radiation layer is stacked on a surface of said current blocking layer, and
said pad electrode is formed on a region stacked with at least one of said current blocking layer and said heat-radiation layer.

4. The semiconductor laser device according to claim 2, wherein
said pad electrode is in contact with said heat-radiation layer on the region other than the vicinity of the region formed with said cavity facet.

5. The semiconductor laser device according to claim 1, wherein
a thickness of said heat-radiation layer is larger than a thickness of said current blocking layer.

6. The semiconductor laser device according to claim 1, wherein
a region other than the vicinity of said current path of said semiconductor device layer is exposed from said current blocking layer, and
said heat-radiation layer is formed on an upper surface of said semiconductor device layer exposed from said current blocking layer.

7. The semiconductor laser device according to claim 1, wherein
said semiconductor device layer is formed with a planar portion and a striped projecting portion protruding upward from said planar portion and extending along a cavity direction on an upper surface, and
said current blocking layer covers side surfaces of said projecting portion, so that said current path is formed on said semiconductor layer in the vicinity of said emission layer.

8. The semiconductor laser device according to claim 1, further comprising a metal electrode layer formed on a surface of said current path, wherein
said heat-radiation layer is in contact with said metal electrode layer.

9. The semiconductor laser device according to claim 8, wherein
said heat-radiation layer is formed on at least a surface of said metal electrode layer of an upper portion of a region formed with said current path in the vicinity of said cavity facet.

10. The semiconductor laser device according to claim 8, wherein
said semiconductor device layer has a region not formed with said metal electrode layer in the vicinity of the region formed with said cavity facet, and
said heat-radiation layer is formed on a surface of said region.

11. The semiconductor laser device according to claim 1, wherein
a refractive index of said current blocking layer is smaller than a refractive index of said heat-radiation layer.

12. The semiconductor laser device according to claim 1, wherein
said heat-radiation layer is made of any of semiconductor, dielectric or metal oxide.

13. The semiconductor laser device according to claim 1, wherein
said heat-radiation layer is made of a single layer or a laminate of at least two layers made of at least any material selected from a group consisting of AlN, Si, SiN, SiC, Al₂O₃, ZnO and ITO.

14. The semiconductor laser device according to claim 1, wherein
said heat-radiation layer includes a first heat-radiation layer and a second heat-radiation layer formed on a surface of said first heat-radiation layer on a side opposite to said semiconductor device layer, and
said second heat-radiation layer is an oxide film.

15. The semiconductor laser device according to claim 1, further comprising a facet protective film formed on said cavity facet.

16. The semiconductor laser device according to claim 15, wherein
said facet protective film is in contact with a surface of said heat-radiation layer located in the vicinity of the region formed with said cavity facet.

17. A method of manufacturing a semiconductor laser device, comprising steps of:
forming a semiconductor device layer having an emission layer and formed with a current path on a semiconductor layer in the vicinity of said emission layer;
forming a current blocking layer on a region in the vicinity of said current path; and
forming a heat-radiation layer having thermal conductivity larger than that of said current blocking layer at least in the vicinity of a region formed with a cavity facet of said semiconductor device layer and above said current path.

18. The method of manufacturing a semiconductor laser device according to claim 17, further comprising a step of forming a pad electrode on a region other than the vicinity of the region formed with said cavity facet of said semiconductor device layer after said step of forming said heat-radiation layer, wherein
said step of forming said pad electrode includes a step of forming said pad electrode on a region formed with at least one of said current blocking layer and said heat-radiation layer.

19. The method of manufacturing a semiconductor laser device according to claim 17, further comprising a step of forming said cavity facet on said semiconductor device layer by cleaving a portion of said semiconductor device layer corresponding to a region formed with said heat-radiation layer after said step of forming said heat-radiation layer.

20. An optical pickup comprising:
a semiconductor laser device including a semiconductor device layer having an emission layer and formed with a current path on a semiconductor layer in the vicinity of said emission layer, a current blocking layer formed in the vicinity of said current path, and a heat-radiation layer formed to be provided at least in the vicinity of a region formed with a cavity facet of said semiconductor device layer and be located above said current path, and having thermal conductivity larger than that of said current blocking layer;
an optical system controlling emitted light of said semiconductor laser device; and
a light detection portion detecting said emitted light.
